(19) United States
(12) Patent Application Publication
(10) Pub. No.: US 2026/0231651 A1
(43) Pub. Date: Aug. 6, 2026

(54) DISPLAY PANEL AND DISPLAY APPARATUS

(71) Applicants: Beijing BOE Technology Development Co., Ltd., Beijing (CN); BOE Technology Group Co., Ltd., Beijing (CN)

(72) Inventors: Hao ZHANG, Beijing (CN); Hejin WANG, Beijing (CN)

(73) Assignees: Beijing BOE Technology Development Co., Ltd., Beijing (CN); BOE Technology Group Co., Ltd., Beijing (CN)

(21) Appl. No.: 19/147,333

(22) PCT Filed: Jul. 4, 2024
(86) PCT No.: PCT/CN2024/103725

§ 371 Date: Jul. 11, 2025

(30) Foreign Application Priority Data
Aug. 31, 2023 (CN) 202311119302.6

(51) Int. Cl. H10K 59/80; G09G 3/20; H10K 59/131

(52) U.S. Cl. CPC H10K 59/873; H10K 59/131; G09G 3/20; G09G 2300/0426; G09G 2300/0819; G09G 2300/0842; G09G 2300/0861

(57) ABSTRACT

A display panel has a main display area and a secondary display area located on at least one side of the main display area. The display panel includes a substrate, a plurality of pixel units and a plurality of openings. The plurality of pixel units include a plurality of first pixel units located in the main display area and a plurality of second pixel units located in the secondary display area. A light transmittance of the main display area is less than that of the secondary display area. The plurality of openings at least penetrate through the substrate. The plurality of openings are located in the secondary display area, multiple second pixel units are arranged around at least one of the plurality of openings, and orthographic projections of the plurality of openings on the substrate are non-overlapping with orthographic projections of the plurality of second pixel units on the substrate.

### CROSS-REFERENCE TO RELATED APPLICATIONS

This application is a national phase entry under 35 USC 371 of International Patent Application No. PCT/CN2024/103725, filed on Jul. 4, 2024, which claims priority to Chinese Patent Application No. 202311119302.6, filed on Aug. 31, 2023, each are incorporated herein by reference in their entirety.

### TECHNICAL FIELD

The present disclosure relates to the field of display technologies, and in particular, to a display panel and a display apparatus.

### BACKGROUND

With the development of display technology, full display with camera (FDC) has been gradually applied to display products due to its advantage of a larger screen-to-body ratio. Full-screen display devices usually place optical components such as cameras in the area under the display panel, greatly increasing the screen-to-body ratio.

### SUMMARY

In an aspect, a display panel is provided. The display panel has a main display area and a secondary display area located on at least one side of the main display area. The display panel includes a substrate, a plurality of pixel units and a plurality of openings. The plurality of pixel units are located on a side of the substrate. The plurality of pixel units include a plurality of first pixel units and a plurality of second pixel units; the plurality of first pixel units are located in the main display area, and the plurality of second pixel units are located in the secondary display area. A light transmittance of the main display area is less than a light transmittance of the secondary display area. The plurality of openings at least penetrate through the substrate. The plurality of openings are located in the secondary display area, multiple second pixel units are arranged around at least one of the plurality of openings, and orthographic projections of the plurality of openings on the substrate are non-overlapping with orthographic projections of the plurality of second pixel units on the substrate.

In some embodiments, the substrate includes a first sub-substrate located in the main display area and a second sub-substrate located in the secondary display area, and the first sub-substrate and the second sub-substrate are connected. The plurality of first pixel units are located on the first sub-substrate. The second sub-substrate includes a plurality of island portions and a plurality of bridge portions. The plurality of island portions are arranged in multiple rows and multiple columns. Each island portion is provided thereon with at least one second pixel unit in the plurality of second pixel units. The plurality of bridge portions are located between island portions in a same row and between island portions in a same column; and two adjacent island portions are connected by a bridge portion in the plurality of bridge portions. Island portions and bridge portions are arranged around the at least one opening.

In some embodiments, a pixel unit in the plurality of pixel units includes a pixel circuit; a first pixel unit in the plurality of first pixel units includes a first pixel circuit, and a second pixel unit in the plurality of second pixel units includes a second pixel circuit. Pixel circuits of the plurality of pixel units are arranged in multiple rows, and the multiple rows of pixel circuits includes a plurality of first-type pixel circuit rows. A first-type pixel circuit row in the plurality of first-type pixel circuit rows includes first pixel circuits and second pixel circuits; and in a row direction, the first pixel circuits in the first-type pixel circuit row are located at two opposite sides of the secondary display area. The display panel further includes a first-type signal line electrically connected to pixel circuits in the first-type pixel circuit row. In the row direction, the first-type signal line passes through the secondary display area from the main display area through multiple island portions where the second pixel circuits in the first-type pixel circuit row are located and multiple bridge portions arranged in the same row as the multiple island portions.

In some embodiments, the multiple rows of pixel circuits further include a plurality of second-type pixel circuit rows. A second-type pixel circuit row in the plurality of second-type pixel circuit rows includes first pixel circuits; in the row direction, the first pixel circuits in the second-type pixel circuit row are located at two opposite sides of the secondary display area; and in a column direction, at least one second-type pixel circuit row is arranged between two adjacent first-type pixel circuit rows. The display panel further includes a second-type signal line electrically connected to pixel circuits in the second-type pixel circuit row. In the row direction, a portion of the second-type signal line close to the secondary display area extends to an adjacent island portion or bridge portion along a border of the secondary display area, and another portion of the second-type signal line connected to the portion close to the secondary display area passes through the secondary display area through island portions and bridge portions arranged in a same row as the adjacent island portion or bridge portion.

In some embodiments, a portion of the second-type signal line located on the island portion extends in a border of the island portion.

In some embodiments, a portion of the second-type signal line located on the island portion is non-overlapping with a second pixel circuit located on the island portion.

In some embodiments, signals transmitted by the first-type signal line and the second-type signal line are the same.

In some embodiments, the first-type signal line includes at least one of scan signal lines, enable signal lines, and initial signal lines.

In some embodiments, there are multiple second pixel units on the island portion; for the island portions located in the same row, second pixel circuits of second pixel units on each island portion are arranged in a same row.

In some embodiments, a pixel unit in the plurality of pixel units includes a pixel circuit; a first pixel unit in the plurality of first pixel units includes a first pixel circuit, and a second pixel unit in the plurality of second pixel units includes a second pixel circuit. Pixel circuits of the plurality of pixel units are arranged in multiple columns, and the multiple columns of pixel circuits includes a plurality of first-type pixel circuit columns. A first-type pixel circuit column in the plurality of first-type pixel circuit columns includes first pixel circuits and second pixel circuits; and in a column direction, the first pixel circuits in the first-type pixel circuit column are located at two opposite sides of the secondary display area. The display panel further includes a third-type signal line electrically connected to pixel circuits in the first-type pixel circuit column. In the column direction, the third-type signal line passes through the secondary display area from the main display area through multiple island portions where the second pixel circuits in the first-type pixel circuit column are located and multiple bridge portions arranged in the same column as the multiple island portions.

In some embodiments, the multiple columns of pixel circuits further include a plurality of second-type pixel circuit columns. A second-type pixel circuit column in the plurality of second-type pixel circuit columns includes first pixel circuits; in the column direction, the first pixel circuits in the second-type pixel circuit column are located at two opposite sides of the secondary display area; and in the row direction, at least one second-type pixel circuit column is arranged between two adjacent first-type pixel circuit columns. The display panel further includes a fourth-type signal line electrically connected to pixel circuits in the second-type pixel circuit column. In the column direction, a portion of the fourth-type signal line close to the secondary display area extends to an adjacent island portion or bridge portion along a border of the secondary display area, and another portion of the fourth-type signal line connected to the portion close to the secondary display area passes through the secondary display area through island portions and bridge portions arranged in a same column as the adjacent island portion or bridge portion.

In some embodiments, a portion of the fourth-type signal line located on the island portion extends in a border of the island portion.

In some embodiments, a portion of the fourth-type signal line located on the island portion is non-overlapping with a second pixel circuit located on the island portion.

In some embodiments, the multiple columns of pixel circuits further include a plurality of second-type pixel circuit columns. A second-type pixel circuit column in the plurality of second-type pixel circuit columns includes first pixel circuits; in the column direction, the first pixel circuits in the second-type pixel circuit column are located at two opposite sides of the secondary display area; and in the row direction, at least one second-type pixel circuit column is arranged between two adjacent first-type pixel circuit columns. The display panel further includes a fourth-type signal line electrically connected to pixel circuits in the second-type pixel circuit column, and the fourth-type signal line is located in the main display area. In the column direction, a portion of the fourth-type signal line close to the secondary display area extends from a first side of the secondary display area along borders of the secondary display area to a second side of the secondary display area; and the first side and second side of the secondary display area are two opposite sides of the secondary display area in the column direction.

In some embodiments, there are multiple second pixel units on the island portion; for the island portions located in the same column, second pixel circuits of second pixel units on each island portion are arranged in a same column.

In some examples, signals transmitted by the third-type signal line and the fourth-type signal line are the same.

In some embodiments, the third-type signal line includes at least one of data signal lines and first voltage signal lines.

In some embodiments, a pixel unit in the plurality of pixel units includes a pixel circuit. A first pixel unit in the plurality of first pixel units includes a first pixel circuit and a first electrode pattern located on a side of the first pixel circuit away from the first sub-substrate; and a plurality of first electrode patterns are connected to form a one-piece structure. A second pixel unit in the plurality of second pixel units includes a second pixel circuit and a second electrode pattern located on a side of the second pixel circuit away from the island portion. Second electrode patterns on different island portions are arranged independently of each other; or the display panel includes a connection pattern located on the bridge portion, second electrode patterns on two adjacent island portions are connected by the connection pattern, and the second electrode patterns are further connected to the first electrode pattern.

In some embodiments, in a case where the second electrode patterns are connected to the connection pattern and the first electrode pattern, the display panel further includes a plurality of first barrier dam groups located in the secondary display area. A first barrier dam group in the plurality of first barrier dam groups surrounds a single opening in the plurality of openings, and the first barrier dam group is further located between the second pixel circuit and an adjacent opening.

In some embodiments, the first barrier dam group includes at least one barrier dam; and in a case where the first barrier dam group includes a plurality of barrier dams, the plurality of barrier dams are arranged concentrically and at intervals.

In some embodiments, in a case where the second electrode patterns on different island portions are arranged independently of each other, the display panel further includes a fifth-type signal line for transmitting a common voltage signal. The fifth-type signal line includes at least one first signal sub-line extending in a column direction and a plurality of second signal sub-lines extending in a row direction. A first signal sub-line in the at least one first signal sub-line is located in the main display area; a second signal sub-line in the plurality of second signal sub-lines is located in the secondary display area and extends to the main display area through island portions and bridge portions located in the same row to be connected to the first signal sub-line; and the second signal sub-line is further connected to the second electrode pattern on each island portion through which the second signal sub-line passes.

In some embodiments, the first signal sub-line, the second signal sub-line and the second electrode pattern are located in different layers.

In some embodiments, the display panel further includes a second barrier dam group and a plurality of third barrier dam groups located in the secondary display area. The second barrier dam group is arranged in borders of the secondary display area and surrounds the secondary display area. A third barrier dam group in the plurality of third barrier dam groups is located on a single island portion in the plurality of island portions, and the third barrier dam group is arranged in borders of the corresponding island portion and surrounds the at least one second pixel unit on the corresponding island portion.

In some embodiments, the second barrier dam group includes at least one barrier dam; in a case where the second barrier dam group includes a plurality of barrier dams, the plurality of barrier dams are arranged concentrically and at intervals. The third barrier dam group includes at least one barrier dam; in a case where the third barrier dam group includes a plurality of barrier dams, the plurality of barrier dams are arranged concentrically and at intervals.

In another aspect, a display apparatus is provided. The display apparatus includes the display panel as described in any one of the above embodiments and an optical element. The optical element is located on a non-light-exit side of the display panel, and is located on the secondary display area of the display panel.

### BRIEF DESCRIPTION OF THE DRAWINGS

In order to describe technical solutions in the present disclosure more clearly, the accompanying drawings to be used in some embodiments of the present disclosure will be introduced briefly. Obviously, the accompanying drawings to be described below are merely accompanying drawings of some embodiments of the present disclosure, and a person of ordinary skill in the art can obtain other accompanying drawings according to those accompanying drawings. In addition, the accompanying drawings in the following description may be regarded as schematic diagrams, but are not limitations on actual sizes of products involved in the embodiments of the present disclosure.

FIG. 1 is a schematic diagram of a display apparatus, in accordance with some embodiments of the present disclosure;

FIG. 2 is a schematic diagram of another display apparatus, in accordance with some embodiments of the present disclosure;

FIG. 3 is a structural diagram of a display panel, in accordance with some embodiments of the present disclosure;

FIG. 4 is a structural diagram of another display panel, in accordance with some embodiments of the present disclosure;

FIG. 5 is a structural diagram of yet another display panel, in accordance with some embodiments of the present disclosure;

FIG. 6 is a structural diagram of yet another display panel, in accordance with some embodiments of the present disclosure;

FIG. 7 is a structural diagram of a substrate, in accordance with some embodiments of the present disclosure;

FIG. 8 is a structural diagram of a section of the display panel in FIG. 5 taken along the direction FF;

FIG. 9 is an equivalent circuit diagram of a pixel circuit and a light-emitting device, in accordance with some embodiments of the present disclosure;

FIG. 10 is an equivalent circuit diagram of another pixel circuit and a light-emitting device, in accordance with some embodiments of the present disclosure;

FIG. 11 is a structural diagram of yet another display panel, in accordance with some embodiments of the present disclosure;

FIG. 12 is a structural diagram of yet another display panel, in accordance with some embodiments of the present disclosure;

FIG. 13 is a structural diagram of yet another display panel, in accordance with some embodiments of the present disclosure;

FIGS. 14 to 24 are top views of some film layers in a display panel, in accordance with some embodiments of the present disclosure;

FIG. 25 is a top view of a first electrode layer, in accordance with some embodiments of the present disclosure;

FIG. 26 is a top view of another first electrode layer, in accordance with some embodiments of the present disclosure;

FIG. 27 is a partial structural diagram of a secondary display area of a display panel, in accordance with some embodiments of the present disclosure;

FIG. 28 is a structural diagram of a section of the display panel in FIG. 27 taken along the direction GG;

FIGS. 29 to 33 are top views of some film layers in another display panel, in accordance with some embodiments of the present disclosure; and

FIG. 34 is a partial structural diagram of a secondary display area of another display panel, in accordance with some embodiments of the present disclosure.

### DETAILED DESCRIPTION

The technical solutions in some embodiments of the present disclosure will be described clearly and completely below with reference to the accompanying drawings, and obviously, the described embodiments are merely some but not all embodiments of the present disclosure. All other embodiments obtained by a person of ordinary skill in the art based on the embodiments provided in the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example”, or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a/the plurality of” means two or more unless otherwise specified.

The phrase “A and/or B” includes following three combinations: only A, only B, and a combination of A and B.

As used herein, the term such as “about”, “substantially” or “approximately” includes a stated value and an average value within an acceptable range of deviation of a particular value, and the acceptable range of deviation is determined by a person of ordinary skill in the art in view of measurement in question and errors associated with measurement of a particular quantity (i.e., limitations of a measurement system).

The term such as “perpendicular” or “equal” as used herein includes a stated case and a case similar to the stated case within an acceptable range of deviation, and the acceptable range of deviation is determined by a person of ordinary skill in the art, considering measurement in question and errors associated with measurement of a particular quantity (i.e., limitations of a measurement system). For example, the term “perpendicular” includes absolute perpendicularity and approximate perpendicularity, and an acceptable range of deviation of the approximate perpendicularity may be, for example, a deviation within 5°; and the term “equal” includes absolute equality and approximate equality, and an acceptable range of deviation of the approximate equality may be, for example, a difference between two equals being less than or equal to 5% of either of the two equals.

It should be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary accompanying drawings. In the accompanying drawings, thicknesses of layers and sizes of regions are enlarged for clarity. Variations in shape relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of regions in apparatuses, and are not intended to limit the scope of the exemplary embodiments.

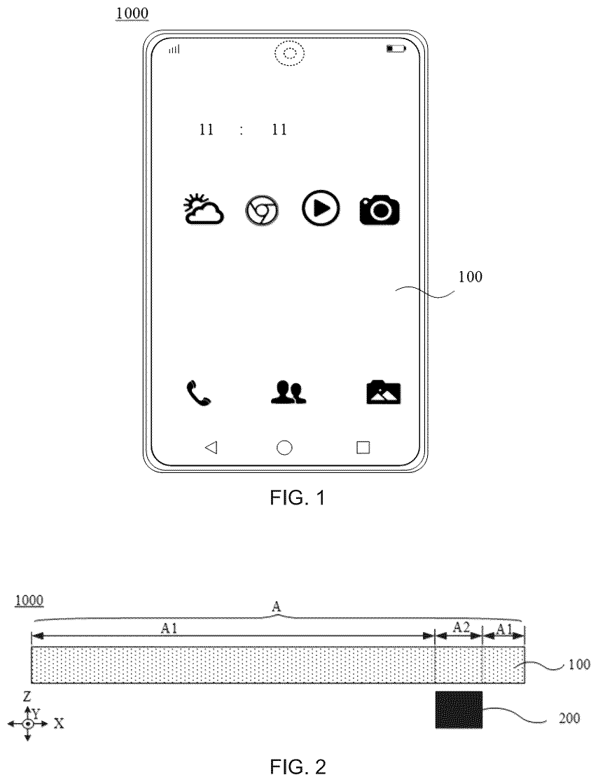

As shown in FIG. 1, some embodiments of the present disclosure provide a display apparatus 1000. The display apparatus 1000 may be any display apparatus that displays images whether in motion (e.g., videos) or stationary (e.g., static images), and whether textual or graphical. More specifically, it is expected that the display apparatus in the embodiments may be implemented in or associated with a variety of electronic apparatuses. The variety of electronic apparatuses may include (but are not limited to), for example, mobile phones, wireless apparatuses, personal digital assistants (PDAs), hand-held or portable computers, global positioning system (GPS) receivers/navigators, cameras, MP4 video players, video cameras, game consoles, watches, clocks, calculators, television monitors, flat panel displays, computer monitors, car displays (such as odometer displays), navigators, cockpit controllers and/or displays, camera view displays (such as rear view camera displays in vehicles), electronic photos, electronic billboards or indicators, projectors, building structures, packaging and aesthetic structures (such as displays for an image of a piece of jewelry), etc.

The display apparatus 1000 includes a frame, a display driver integrated circuit (IC) and other electrical components.

In some examples, as shown in FIG. 2, the display apparatus 1000 further includes a display panel 100 and an optical element 200. The display panel 100 is embedded in the frame, and the display panel 100 is electrically connected to the display driver IC to receive display signals provided by the display driver IC.

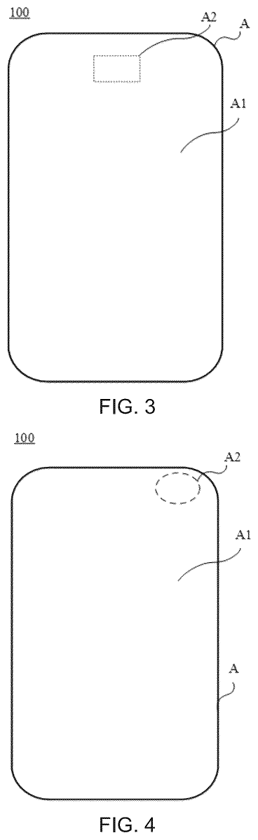

For example, as shown in FIGS. 2 to 4, the display panel 100 has a display area A, and the display area A is a region of the display panel 100 for displaying images.

The display area A may be in a shape of a rectangle or a rounded rectangle. The rounded rectangle refers to a rectangle with four rounded corners.

The display area A includes a main display area A1 and a secondary display area A2 located on at least one side of the main display area A1.

For example, the secondary display area A2 is in a shape of a circle, an ellipse, or a rectangle.

For example, the secondary display area A2 is located on one or more sides of the main display area A1.

For example, in a case where the display area A is in the shape of the rectangle, the secondary display area A2 can be located at any position in the middle of the rectangle, or the secondary display area A2 can be located at a position close to any corner of the rectangle, or the secondary display area A2 can be located at a position close to any side of the rectangle.

For example, in the display panel 100, portions located in the main display area A1 and the secondary display area A2 can both be used for image display.

For example, a light transmittance of the secondary display area A2 is greater than a light transmittance of the main display region A1.

For example, the optical element 200 is located on a non-light-exit side of the display panel 100, and is located on the secondary display area A2 of the display panel 100.

A light-exit side of the display panel 100 refers to a side of the display panel 100 that is capable of displaying images, and the non-light-exit side of the display panel 100 refers to a side of the display panel 100 opposite to the light-exit side. Since the light transmittance of the secondary display area A2 is greater than that of the main display area A1, external light has less loss after passing through the secondary display area A2, and the optical element 200 can obtain sufficient light to avoid affecting the function of the optical element 200.

For example, as shown in FIG. 2, the optical element 200 is a camera, a fingerprint recognition sensor, an infrared sensor, or the like.

When the optical element 200 is working, it is necessary for external light to pass through the secondary display area A2 and then be incident onto the optical element 200, so that a corresponding function of the optical element 200 is activated. The embodiments of the present disclosure are described by taking an example in which the optical element 200 is the camera.

For example, during a working process of the camera, the external light can pass through a portion of the display panel 100 located in the secondary display area A2. In this way, the camera may collect the light to achieve a function of taking photos or recording videos. For example, when the camera is working (e.g., the user is taking a selfie), the secondary display area A2 presents a black image, and the main display area A1 presents the user's selfie image, which more clearly shows the location of the camera. Alternatively, the secondary display area A2 and the main display area A1 present the user's selfie image as a whole, without showing the location of the camera.

For example, when the camera is not working, the portions of the display panel 100 located in the secondary display area A2 and the main display area A1 can both display images, so that the entire display panel 100 and the entire display apparatus 1000 can display images.

In an implementation, in the display panel of the display apparatus, the light transmittance of the secondary display area is low, so that less light is incident onto the camera through the secondary display area, and the light collected by the camera is limited, which affects imaging clarity of the camera.

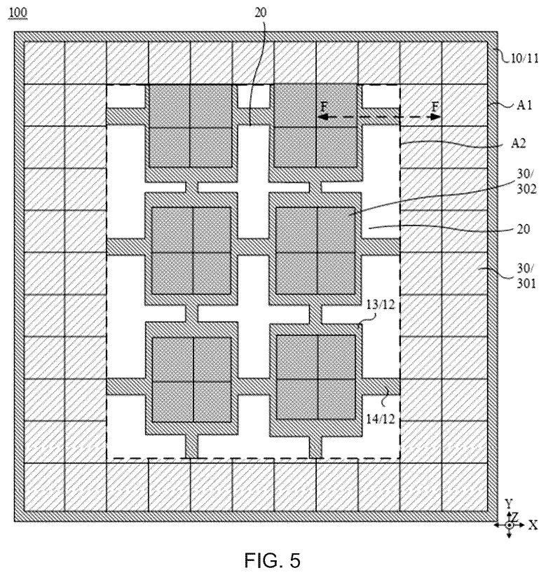

In light of this, in some examples of the present disclosure, as shown in FIG. 5, the display panel 100 includes a substrate 10 and a pixel unit layer.

The substrate 10 may be a rigid substrate, and a material of the rigid substrate may be glass. The substrate 10 may also be a flexible substrate, and a material of the flexible substrate may be dimethylsiloxane, polyimide (PI), polyethylene terephthalate (PET), or other high elastic material.

The pixel unit layer includes a plurality of pixel units 30 located on a side of the substrate 10 (e.g., located on a surface of the substrate 100. The plurality of pixel units 30 interact with each other to be used to display images.

As shown in FIG. 5, the plurality of pixel units 30 include a plurality of first pixel units 301 and a plurality of second pixel units 302. The plurality of first pixel units 301 are located in the main display area A1, and the plurality of second pixel units 302 are located in the secondary display area A2. Thus, both the main display area A1 and the secondary display area A2 of the display panel 100 can display images.

Structures of the first pixel unit 301 and the second pixel unit 302 may be the same or similar. In a case where the structures of the first pixel unit 301 and the second pixel unit 302 are the same, a size of the first pixel unit 301 may be the same as that of the second pixel unit 302, or the size of the first pixel unit 301 may be greater than that of the second pixel unit 302. Here, the size may be an area of an orthographic projection of the pixel unit 30 on a plane where the substrate 10 is located.

For example, as shown in FIG. 5, a distribution density of the plurality of first pixel units 301 is greater than a distribution density of the plurality of second pixel units 302. The greater the distribution density of the pixel units 30 is, the greater the pixel density of the display panel 100 is. Thus, in the display panel 100, the pixel density of the main display area A1 is greater than the pixel density of the secondary display area A2.

In addition, the second pixel units 302 can block light that directs towards the optical element 200 through the secondary display area A2 of the display panel 100, which makes it almost impossible for the light to pass through. By setting the distribution density of the plurality of first pixel units 301 to be greater than the distribution density of the plurality of second pixel units 302, an area occupied by the plurality of second pixel units 302 is relatively small. Thus, the light blocked by the second pixel units 302 may be relatively small. Moreover, a portion of the substrate 10 located between two adjacent second pixel units 302 (it can be understood that the light transmittance of this portion to external light is greater than the light transmittance of the second pixel unit 302 to the light) has a large area, and more light is incident onto the optical element 200 after passing through this portion in the secondary display area A2, thereby ensuring that the optical element 200 can work normally.

For example, the distribution density of the first pixel units 301 may be less than or equal to the distribution density of the second pixel units 302. Thus, the pixel density of the secondary display area A2 is relatively large, which is beneficial to improving the display quality of the secondary display area A2 of the display panel 100.

For example, as shown in FIG. 5, the display panel 100 further includes a plurality of openings 20 that at least penetrate through the substrate 10. The plurality of openings 20 are located in the secondary display area A2.

For example, the plurality of openings 20 penetrate through the pixel unit layer and the substrate 10, and the openings 20 penetrate through the entire display panel 100 to form hollow regions of the display panel 100. The external light can be incident onto the optical element 200 through the plurality of openings 20 (that is, the external light can be directly incident onto the optical element 200 through the space within the openings 20). Therefore, compared with the path of the external light passing through the portion of the substrate between two adjacent second pixel units 302 and then reaching the optical element 200, the external light is incident onto the optical element 200 through the openings 20, which may further improve the light transmittance of the secondary display area A2. As a result, the optical element 200 may collect enough light, thereby ensuring that the optical element 200 works normally using the light, and improving the performances of the optical element 200 (for example, making imaging of the camera clear and having good imaging effects.

Multiple second pixel units 302 are arranged around at least one of the plurality of openings 20. Orthographic projections of the plurality of openings 20 on the substrate 10 are non-overlapping with orthographic projections of the plurality of second pixel units 302 on the substrate 10. For example, among the plurality of openings 20, an opening 20 close to a border line of the secondary display area A2 is further surrounded by multiple first pixel units 301. Among the plurality of openings 20, an opening 20 approximately located in a middle region of the secondary display area A2 is surrounded by only multiple second pixel units 302. There is no overlapping region between the orthographic projections of the plurality of openings 20 on the substrate 10 and the orthographic projections of the plurality of second pixel units 302 on the substrate 10.

For example, the opening 20 is surrounded by at least one sidewall, and the sidewall of the opening 20 is perpendicular or substantially perpendicular to the plane where the substrate 10 is located. The sidewall of the opening 20 has a certain height. Here, the height refers to a dimension of the sidewall of the opening 20 in a thickness direction of the substrate 10.

For example, shapes of the plurality of openings 20 may be varied, which may be set according to actual needs.

For example, as shown in FIG. 5, the orthographic projection of the opening 20 on the plane where the substrate 10 is located can be substantially in a shape of “cross”, and the opening 20 has a plurality of sidewalls connected; and among the plurality of sidewalls, an included angle between two connected sidewalls is a right angle or substantially a right angle. Therefore, the manufacturing of the opening 20 may be more convenient, which is beneficial to simplifying the manufacturing process of the display panel 100 and the display apparatus 1000.

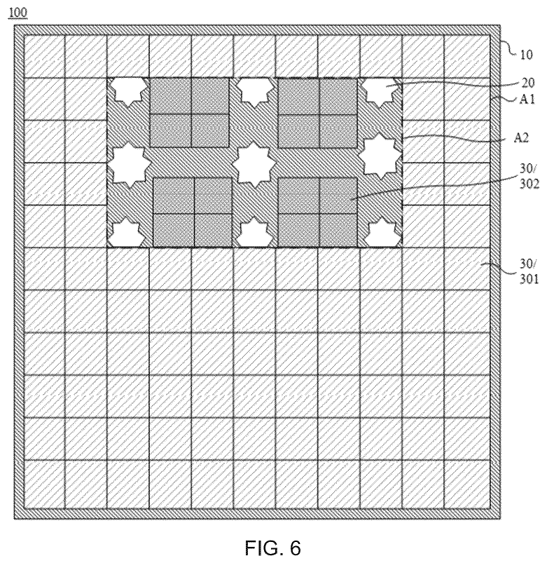

For another example, as shown in FIG. 6, a border line of the orthographic projection of the opening 20 on the plane where the substrate 10 is located is in a sawtooth shape. In a process of the external light passing through the opening 20 to be incident onto the optical element 200, the above arrangement may reduce a probability of interference or diffraction between the external light and the plurality of sidewalls of the opening 20, thereby preventing interference light or diffracted light from entering the camera and preventing affecting the imaging quality.

The shapes of the orthographic projections of the plurality of openings 20 on the plane where the substrate 10 is located may be the same or different. For example, the shapes of multiple openings 20 away from the border line of the secondary display area A2 are different from the shapes of multiple openings 20 close to the border line of the secondary display area A2.

Some embodiments of the present disclosure provide a display panel 100, the display panel 100 has a main display area A1 and a secondary display area A2 located on at least one side of the main display area A1, and the display panel 100 includes a substrate 10 and a plurality of pixel units 30 located on the substrate 10; first pixel units 301 are located in the main display area A1, second pixel units 302 are located in the secondary display area A2, and a light transmittance of the main display area A1 is less than that of the secondary display area A2. Moreover, in the embodiments of the present disclosure, the display panel 100 further includes a plurality of openings 20 penetrating through the substrate 10, the plurality of openings 20 are located in the secondary display area A2, and an opening 20 is surrounded by multiple second pixel units 302. As a result, for light incident from the secondary display area A2 from the outside, the light directly passes through the plurality of openings 20 to be incident onto the optical element 200, rather than passing through a plurality of solid film layers (e.g., the substrate 10 and other film layers), thereby effectively reducing the loss of light in the process of passing through the solid film layers, and further increasing the light transmittance of the secondary display area A2. Therefore, in a case where the display panel 100 is applied to the display apparatus 1000, the intensity of light reaching the optical element 200 is relatively great, and more light reaches the optical element 200, thereby ensuring the normal operation of the optical element 200.

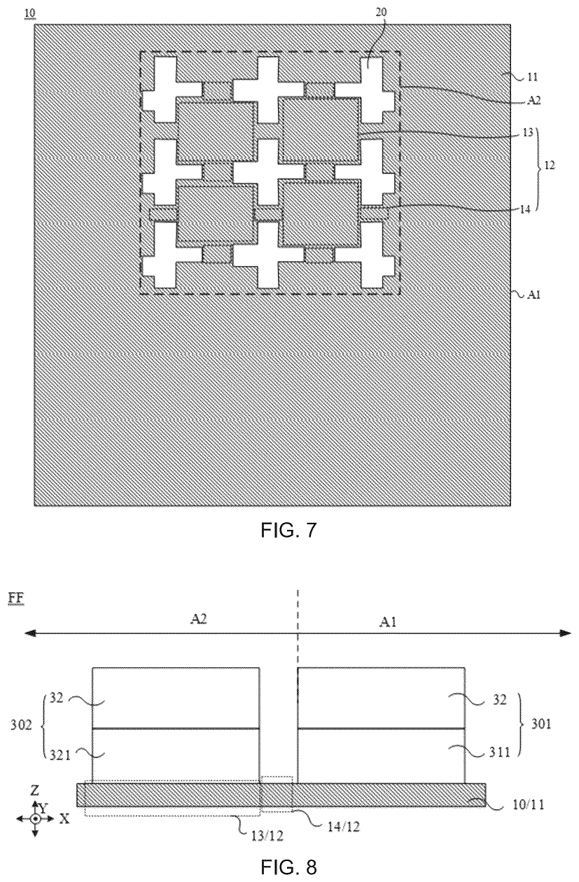

In some examples, as shown in FIG. 7, the substrate 10 includes a first sub-substrate 11 and a second sub-substrate 12 that are connected. The first sub-substrate 11 is located in the main display area A1, and the second sub-substrate 12 is located in the secondary display area A2.

The plurality of first pixel units 301 are located on the first sub-substrate 11.

The second sub-substrate 12 includes a plurality of island portions 13 and a plurality of bridge portions 14. For example, an area of the island portion 13 is greater than an area of the bridge portion 14. The areas of the island portions 13 may be substantially equal, and the areas of the bridge portions 14 may be substantially equal.

The plurality of island portions 13 are arranged in multiple rows and multiple columns. Each island portion 13 is provided with at least one second pixel unit 302 thereon. Multiple bridge portions 14 are located between island portions 13 in the same row, and multiple bridge portions 14 are located between island portions 13 in the same column. Two adjacent island portions 13 are connected by a bridge portion 14.

Of course, a bridge portion 14 close to the border of the secondary display area A2 is further connected to the first sub-substrate 11, and an island portion 13 close to the border of the secondary display area A2 may further be directly connected to the first sub-substrate 11.

As shown in FIGS. 5 and 7, multiple island portions 13 and multiple bridge portions 14 are arranged around at least one opening 20. For example, the island portion 13 and the bridge portion 14 connected in sequence surround a portion of the sidewall of the opening 20. For the opening 20 close to the border of the secondary display area A2, the opening 20 is further surrounded by the first sub-substrate 11, and the first sub-substrate 11 constitutes a portion of the sidewall of the opening 20.

The plurality of second pixel units 302 are arranged around the openings 20, the external light may pass through the secondary display area A2 through the openings 20, and the plurality of second pixel units 302 may also achieve the display function of the secondary display area A2.

For example, the pixel unit 30 constitutes a sub-pixel of the display panel 100, and the plurality of pixel units 30 constitute a plurality of sub-pixels of the display panel 100. The plurality of sub-pixels include a plurality of red sub-pixels, a plurality of green sub-pixels, and a plurality of blue sub-pixels. The red sub-pixel refers to a sub-pixel that emits red light, the green sub-pixel refers to a sub-pixel that emits green light, and the blue sub-pixel refers to a sub-pixel that emits blue light. For example, three pixel units 30 are arranged on a single island portion 13, and the three pixel units 30 are a red sub-pixel, a green sub-pixel, and a blue sub-pixel; alternatively, four pixel units 30 are arranged on a single island portion 13, and the four pixel units 30 are two green sub-pixels, a red sub-pixel, and a blue sub-pixel.

The red sub-pixel, blue sub-pixel and green sub-pixel that are adjacent constitute a pixel of the display panel 100, and light emitted by a plurality of pixels cooperate with each other to form a display image of the display panel 100.

As shown in FIG. 8, the pixel unit 30 includes a pixel circuit 31 and a light-emitting device 32. The pixel circuit 31 is electrically connected to the light-emitting device 32, and the light-emitting device 32 emits light under a signal provided by the pixel circuit 31.

A structure of the pixel circuit 31 varies and can be set according to actual needs. For example, the pixel circuit 31 is of a structure with “6T1C”, “7T1C”, “6T2C”, or “7T2C”. Here, “T” represents a transistor, and the number preceding “T” represents the number of transistors; “C” represents a storage capacitor, and the number preceding “C” represents the number of storage capacitors.

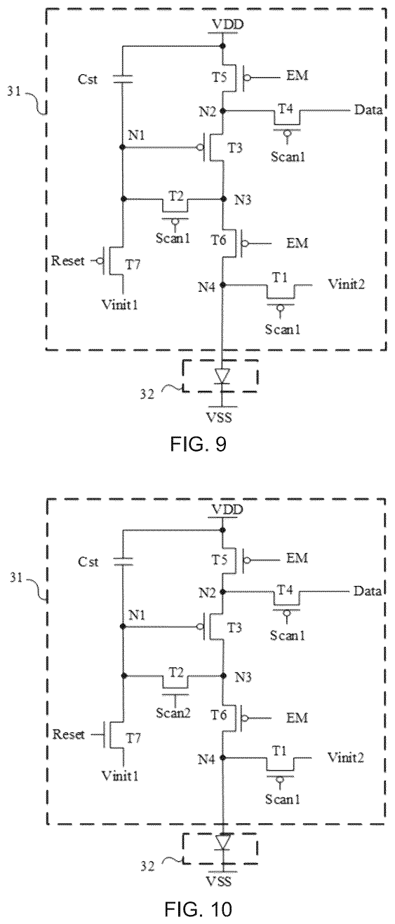

For example, embodiments of the present disclosure will be described by taking an example in which the pixel circuit 31 is of the “7T1C” structure. FIG. 9 shows an equivalent circuit diagram of a sub-pixel.

For example, as shown in FIG. 9, the pixel circuit 31 includes a first reset transistor T1, a compensation transistor T2, a driving transistor T3, a switch transistor T4, a first light-emitting control transistor T5, a second light-emitting control transistor T6, a second reset transistor T7, and a storage capacitor Cst.

For example, as shown in FIG. 9, a control electrode of the second reset transistor T7 is electrically connected to a reset signal terminal Reset, a first electrode of the second reset transistor T7 is electrically connected to a first initial signal terminal Vinit1, and a second electrode of the second reset transistor T7 is electrically connected to a first node N1 (i.e., connected to a second electrode of the compensation transistor T2). The second reset transistor T7 is configured to be turned on under control of a reset signal provided by the reset signal terminal Reset, and transmit a first initial signal received from the first initial signal terminal Vinit1 to the first node N1, so as to reset the first node N1.

For example, as shown in FIG. 9, a control electrode of the first reset transistor T1 is electrically connected to a first scan signal terminal Scan1, a first electrode of the first reset transistor T1 is electrically connected to a second initial signal terminal Vinit2, and a second electrode of the first reset transistor T1 is electrically connected to a fourth node N4. The first reset transistor T1 is configured to be turned on under control of a scan signal provided by the first scan signal terminal Scan1, and transmit a second initial signal received from the second initial signal terminal Vinit2 to the fourth node N4, so as to reset the fourth node N4.

For example, as shown in FIG. 9, a control electrode of the switch transistor T4 is electrically connected to the first scan signal terminal Scan1, a first electrode of the switch transistor T4 is electrically connected to a data signal terminal Data, and a second electrode of the switch transistor T4 is electrically connected to a second node N2. The switch transistor T4 is configured to be turned on under control of the scan signal provided by the first scan signal terminal Scan1, and transmit a data signal transmitted by the data signal terminal Data to the second node N2.

For example, as shown in FIG. 9, a control electrode of the driving transistor T3 is electrically connected to the first node N1, a first electrode of the driving transistor T3 is electrically connected to the second node N2, and a second electrode of the driving transistor T3 is electrically connected to the third node N3. The driving transistor T3 is configured to be turned on under control of a voltage of the first node N1, and transmit a signal (e.g., the data signal) from the second node N2 to the third node N3.

For example, as shown in FIG. 9, a control electrode of the compensation transistor T2 is electrically connected to the first scan signal terminal Scan1, a first electrode of the compensation transistor T2 is electrically connected to the third node N3, and a second electrode of the compensation transistor T2 is electrically connected to the first node N1. The compensation transistor T2 is configured to be turned on under the control of the scan signal provided by the first scan signal terminal Scan1, and transmit the signal (e.g., the data signal) from the third node N3 to the first node N1.

For example, as shown in FIG. 9, a control electrode of the first light-emitting control transistor T5 is electrically connected to an enable signal terminal EM, a first electrode of the first light-emitting control transistor T5 is electrically connected to a first voltage signal terminal VDD, and a second electrode of the first light-emitting control transistor T5 is electrically connected to the second node N2. The first light-emitting control transistor T5 is configured to be turned on under control of an enable signal provided by the enable signal terminal EM, and transmit a voltage signal received from the first voltage signal terminal VDD to the second node N2.

For example, as shown in FIG. 9, a control electrode of the second light-emitting control transistor T6 is electrically connected to the enable signal terminal EM, a first electrode of the second light-emitting control transistor T6 is electrically connected to the third node N3, and a second electrode of the second light-emitting control transistor T6 is electrically connected to the fourth node N4. The second light-emitting control transistor T6 is configured to be turned on under the control of the enable signal provided by the enable signal terminal EM, and transmit the voltage signal from the third node N3 to the fourth node N4.

For example, as shown in FIG. 9, a first electrode of the storage capacitor Cst is electrically connected to the first node N1, and a second electrode of the storage capacitor Cst is electrically connected to the first voltage signal terminal VDD.

One end of the light-emitting device 32 (e.g., a second electrode of the light-emitting device 32 mentioned below) is electrically connected to the fourth node N4, and the other end (e.g., a first electrode of the light-emitting device 32 mentioned below) is electrically connected to a common voltage terminal VSS.

The above is introduced by taking an example in which the transistors in the pixel circuit 31 are all LTPS (low-temperature polycrystalline silicon) transistors.

Of course, the compensation transistor T2 and the second reset transistor T7 in the pixel circuit 31 may be LTPO (low-temperature polycrystalline oxide) transistors, and the remaining transistors in the pixel circuit 31 may be LTPS transistors. In this case, the equivalent circuit of the pixel circuit 31 is as shown in FIG. 10, which is different from the equivalent circuit of FIG. 9 in that the control electrode of the compensation transistor T2 is electrically connected to a second scan signal terminal Scan2, and a scan signal provided by the second scan signal terminal Scan2 is different from the scan signal provided by the first scan signal terminal Scan1.

In some embodiments, as shown in FIG. 8, the first pixel unit 301 includes a first pixel circuit 311, and the second pixel unit 302 includes a second pixel circuit 321. Pixel circuits 31 of the plurality of pixel units 30 include first pixel circuits 311 and second pixel circuits 321. Structures of the first pixel circuit 311 and the second pixel circuit 321 may be the same, both of which are, for example, the above-mentioned “7T1C” structure, thereby simplifying the manufacturing process of the pixel circuit 31.

In some examples, as shown in FIG. 5, there are multiple second pixel units 302 on the island portion 13. For multiple island portions 13 located in the same row, second pixel circuits 321 of second pixel units 302 on the multiple island portions 13 are arranged in at least one row.

For multiple island portions 13 located in the same column, second pixel circuits 321 of second pixel units 302 on the multiple island portions 13 are arranged in at least one column.

For example, in FIG. 5, the first direction X is a row direction, the second direction Y is a column direction, and the third direction Z is a thickness direction of the substrate 10.

Thus, the plurality of second pixel circuits 321 located in the secondary display area A2 are arranged in multiple rows and multiple columns, and the plurality of second pixel circuits 321 are arranged more regularly, which is beneficial to simplifying the layout design of the second pixel circuits 321 and the display panel 100.

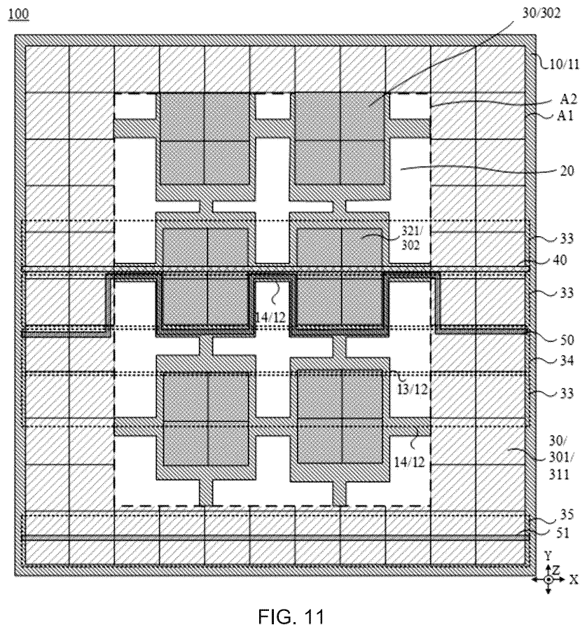

For example, as shown in FIG. 11, the pixel circuits 31 of the plurality of pixel units 30 are arranged in multiple rows, and the multiple rows of pixel circuits 31 includes a plurality of first-type pixel circuit rows 33. The first-type pixel circuit row 33 includes first pixel circuits 311 and second pixel circuits 321. In the row direction, the first pixel circuits 311 in the first-type pixel circuit row 33 are located at two opposite sides of the secondary display area A2. The first-type pixel circuit row 33 passes through the secondary display area A2 from the main display area A1.

As shown in FIG. 11, the display panel 100 further includes a first-type signal line 40 electrically connected to the pixel circuits 31 (i.e., the first pixel circuits 311 and the second pixel circuits 321) in the first-type pixel circuit row 33. The first-type signal line 40 may extend in the first direction X, and the first direction X may be a row direction of the multiple rows of pixel circuits 31. The first-type signal line 40 is used to transmit a signal to the pixel circuits 31 in the first-type pixel circuit row 33.

In the row direction, the first-type signal line 40 passes through the secondary display area A2 from the main display area A1 after passing through multiple island portions 13 where the second pixel circuits 321 in the first-type pixel circuit row 33 are located and multiple bridge portions 14 arranged in the same row as the multiple island portions 13.

For example, a portion of the first-type signal line 40 that passes through the multiple island portions 13 where the second pixel circuits 321 in the first-type pixel circuit row 33 are located has an overlapping portion with the second pixel circuits 321 on the multiple island portions 13. Thus, the electrical connection between the first-type signal line 40 and the second pixel circuits 321 in the first-type pixel circuit row 33 is facilitated.

With the above arrangement, the pixel circuits 31 in the first-type pixel circuit row 33 may be connected to the same first-type signal line 40, so that the difference in signals received by the pixel circuits 31 in the same row from the first-type signal line 40 is relatively small, which is beneficial to reducing the difference in display images of the main display area A1 and the secondary display area A2 of the display panel 100, and to improving the display effect of the display panel 100.

Furthermore, the portion of the first-type signal line 40 passes through the multiple island portions 13 where the second pixel circuits 321 in the first-type pixel circuit row 33 are located and the multiple bridge portions 14 arranged in the same row as the multiple island portions 13, so that a dimension of the first-type signal line 40 may be small, which is beneficial to saving the manufacturing cost of the first-type signal line 40.

In addition, the first-type signal line 40 passes through the secondary display area A2 through the multiple island portions 13 and multiple bridge portions 14, which may avoid the first-type signal line 40 covering or blocking the opening 20, and ensure that the secondary display area A2 has a high light transmittance. Thus, this ensures that the optical element 200 can collect more light and that the optical element 200 works normally.

In some examples, as shown in FIG. 11, the multiple rows of pixel circuits 31 further include a plurality of second-type pixel circuit rows 34. The second-type pixel circuit row 34 includes first pixel circuits 311. In the row direction, the first pixel circuits 311 in the second-type pixel circuit row 34 are located at two opposite sides of the secondary display area A2.

The second-type pixel circuit row 34 does not include second pixel circuits 321.

In the column direction, at least one second-type pixel circuit row 34 is arranged between two adjacent first-type pixel circuit rows 33.

For example, as shown in FIG. 11, in a case where the distribution density of the plurality of first pixel units 301 is slightly different from the distribution density of the plurality of second pixel units 302, one second-type pixel circuit row 34 is arranged between two adjacent first-type pixel circuit rows 33 in the column direction. In this case, the area of the orthographic projection of the opening 20 on the plane where the substrate 10 is located is relatively small. Thus, the display effect of the secondary display area A2 may be relatively good, and the display uniformity of the display area of the display panel 100 is relatively good.

For another example, in a case where the distribution density of the plurality of first pixel units 301 is significantly different from the distribution density of the plurality of second pixel units 302, two or more second-type pixel circuit rows 34 are arranged between two adjacent first-type pixel circuit rows 33 in the column direction. In this case, the area of the orthographic projection of the opening 20 on the plane where the substrate 10 is located is relatively large. Thus, the light transmittance of the secondary display area A2 of the display panel 100 may be relatively high, and the optical element 200 may collect more light, so that the imaging effect is relatively good.

As shown in FIG. 11, the display panel 100 further includes a second-type signal line 50 electrically connected to the pixel circuits 31 (i.e., the first pixel circuits 311) in the second-type pixel circuit row 34. The second-type signal line 50 extends substantially in the first direction X.

In the row direction, a portion of the second-type signal line 50 close to the secondary display area A2 extends to an adjacent island portion 13 or bridge portion 14 along a border of the secondary display area A2, and another portion of the second-type signal line 50 connected to the portion close to the secondary display area A2 passes through the secondary display area A2 through island portions 13 and bridge portions 14 arranged in the same row as the adjacent island portion 13 or bridge portion 14. The second-type signal line 50 passes through the island portion 13 where the second pixel circuit 321 in the first-type pixel circuit row 33 is located, but is not connected to the second pixel circuit 321 on the island portion 13.

The second-type signal line 50 passes through the secondary display area A2, so that a dimension of the second-type signal line 50 may be small, which prevents most portion of the second-type signal line 50 from extending in the border of the secondary display area A2, and prevents the length of the second-type signal line 50 from being large. In addition, the second-type signal line 50 passes through the secondary display area A2 through the island portions 13 and bridge portions 14, which may avoid the second-type signal line 50 covering or blocking the opening 20, and ensure that the secondary display area A2 has a high light transmittance. Thus, this ensures that the optical element 200 can collect more light and that the optical element 200 works normally.

For example, as shown in FIG. 11, a portion of the second-type signal line 50 located on the island portion 13 is non-overlapping with the second pixel circuit 321 located on the island portion 13.

The second pixel circuit 321 on the island portion 13 is connected to the corresponding first-type signal line 40, and the first-type signal line 40 overlaps with the second pixel circuit 321 electrically connected thereto. Therefore, the above arrangement may make a distance between the portion of the first-type signal line 40 located on the island portion 13 and the portion of the second-type signal line 50 located on the island portion 13 relatively large, which may ensure the accuracy of electrical signals transmitted by the first-type signal line 40 and the second-type signal line 50. Accordingly, the signals received by the first-type pixel circuit row 33 and the second-type pixel circuit row 34 are relatively accurate, so that the light-emitting devices 32 electrically connected to the first-type pixel circuit row 33 and the second-type pixel circuit row 34 may perform display normally. As a result, the display panel 100 has a good display effect; it avoids interference between the signals transmitted by the first-type signal line 40 and the second-type signal line 50 due to a small distance between the first-type signal line 40 and the second-type signal line 50, and avoids misconnection between the second-type signal line 50 and the second pixel circuit 321 on the island portion 13.

For example, as shown in FIG. 11, the portion of the second-type signal line 50 located on the island portion 13 extends in the border of the island portion 13, and has a certain distance from the border line of the island portion 13. Thus, an arrangement of a plurality of second-type signal lines 50 may be made regular, and after the plurality of second-type signal lines 50 are regularly arranged, the area of the island portion 13 occupied by the second-type signal line 50 is small, thereby facilitating the arrangement design of other structures (such as the first-type signal lines 40 and the second pixel circuits 321) on the island portion 13. In addition, from the perspective of the manufacturing of the display panel 100 and the display apparatus 1000, the above arrangement may make the area of the island portion 13 designed to be relatively small, while the area of the opening 20 may be designed to be relatively large, which is beneficial to improving the light transmittance of the secondary display area A2 of the display panel 100, allows more light to be incident onto the optical element 200 through the opening 20, and improves the imaging quality of the optical element 200 (e.g., the camera).

For example, the signals transmitted by the first-type signal line 40 and the second-type signal line 50 are the same. In addition, since both the first-type signal line 40 and the second-type signal line 50 pass through the secondary display area A2 from the main display area A1, the signals transmitted by the first-type signal line 40 and the second-type signal line 50 may have substantially the same transmission path from the main display area A1 to the secondary display area A2. Thus, the loss of the signal transmitted by the first-type signal line 40 is substantially the same as the loss of the signal transmitted by the second-type signal line 50, which is beneficial to reducing the difference in signals received by the pixel circuit 31 in the first-type pixel circuit row 33 and the pixel circuit 31 in the second-type pixel circuit row 34, and to improving the display effect of the display panel 100.

The first-type signal lines 40 include at least one of scan signal lines, enable signal lines, and initial signal lines.

For example, the first-type signal lines 40 include scan signal lines, enable signal lines, or initial signal lines.

For another example, the first-type signal lines 40 include scan signal lines and enable signal lines, or include scan signal lines and initial signal lines.

For another example, the first-type signal lines 40 include scan signal lines, enable signal lines, and initial signal lines.

In a case where the first-type signal line 40 is a scan signal line, the first-type signal line 40 may be electrically connected to the first scan signal terminal Scan1 or the second scan signal terminal Scan2 of the pixel circuit 31 to transmit the scan signal to the first scan signal terminal Scan1 or the second scan signal terminal Scan2.

In a case where the first-type signal line 40 is an enable signal line, the first-type signal line 40 may be electrically connected to the enable signal terminal EM of the pixel circuit 31 to transmit the enable signal to the enable signal terminal EM.

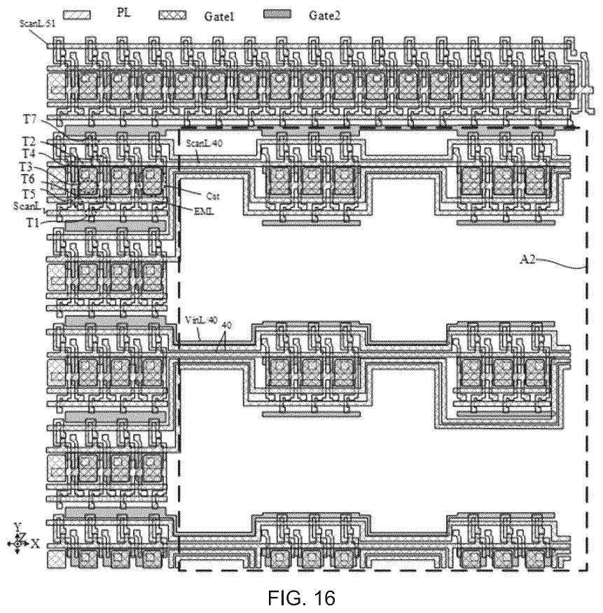

In a case where the first-type signal line 40 is a first initial signal line VinL (see FIG. 16), the first-type signal line 40 may be electrically connected to the first initial signal terminal Vinit1 of the pixel circuit 31 to transmit the first initial signal to the first initial signal terminal Vinit1.

In a case where the first-type signal line 40 is a second initial signal line, the first-type signal line 40 may be electrically connected to the second initial signal terminal Vinit2 of the pixel circuit 31 to transmit the second initial signal to the second initial signal terminal Vinit2.

The reset signal of the pixel circuits in the current row is generally provided by the scan signal line of the pixel circuits in the next row. Here, the first-type signal lines 40 may further include reset signal lines. In a case where the first-type signal line 40 is a reset signal line, the first-type signal line 40 may be electrically connected to the reset signal terminal Reset of the pixel circuit 31 to transmit the reset signal to the reset signal terminal Reset.

It can be understood that, as shown in FIG. 11, the multiple rows of pixel circuits 31 further include a plurality of third-type pixel circuit rows 35, and the third-type pixel circuit row 35 includes first pixel circuits 311. The first pixel circuits 311 in the third-type pixel circuit row 35 are all located at the same side of the secondary display area A2 in the second direction Y.

The display panel 100 further includes a sixth-type signal line 51 electrically connected to the pixel circuits 31 (i.e., the first pixel circuits 311) in the third-type pixel circuit row 35. The sixth-type signal line 51 extends in the first direction X, and the sixth-type signal line is located in the main display area A1.

The signal transmitted by the sixth-type signal line 51 is the same as the signal transmitted by the first-type signal line 40 described above.

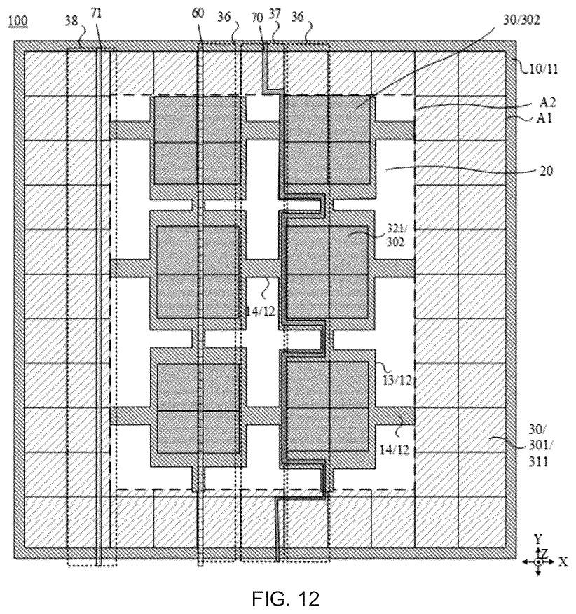

In some examples, as shown in FIG. 12, the pixel circuits 31 of the plurality of pixel units 30 are arranged in multiple columns, and the multiple columns of pixel circuits 31 includes a plurality of first-type pixel circuit columns 36. The first-type pixel circuit column 36 includes first pixel circuits 311 and second pixel circuits 321. In the column direction, the first pixel circuits 311 in the first-type pixel circuit column 36 are located at two opposite sides of the secondary display area A2. The first-type pixel circuit column 36 passes through the secondary display area A2 from the main display area A1.

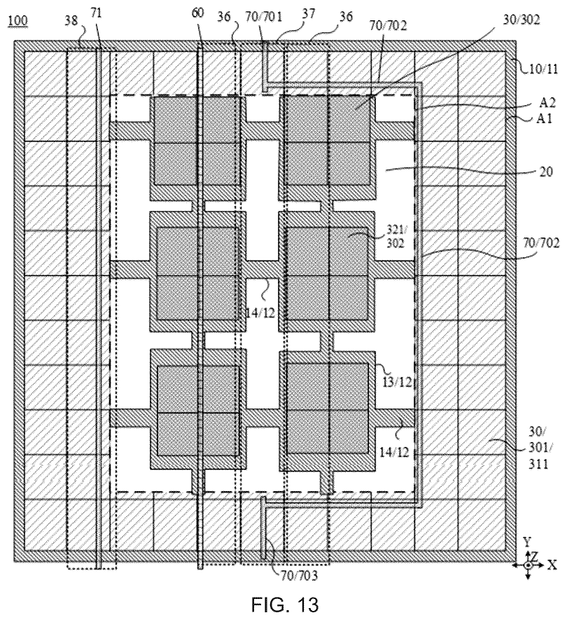

As shown in FIGS. 12 and 13, the display panel 100 further includes a third-type signal line 60 electrically connected to the pixel circuits 31 (i.e., the first pixel circuits 311 and the second pixel circuits 321) in the first-type pixel circuit column 36.

In the column direction, the third-type signal line 60 passes through the secondary display area A2 from the main display area A1 after passing through multiple island portions 13 where the second pixel circuits 321 in the first-type pixel circuit column 36 are located and multiple bridge portions 14 arranged in the same row as the multiple island portions 13.

For example, a portion of the third-type signal line 60 that passes through the multiple island portions 13 where the second pixel circuits 321 in the first-type pixel circuit column 36 are located has an overlapping portion with the second pixel circuits 321 on the multiple island portions 13. Thus, the electrical connection between the third-type signal line 60 and the second pixel circuits 321 in the first-type pixel circuit column 36 is facilitated.

With the above arrangement, the pixel circuits 31 in the first-type pixel circuit column 36 may be connected to the same third-type signal line 60, so that the difference in signals received by the pixel circuits 31 in the same column from the third-type signal line 60 is relatively small, which is beneficial to reducing the difference in display images of the main display area A1 and the secondary display area A2 of the display panel 100, and to improving the display effect of the display panel 100.

Moreover, the portion of the third-type signal line 60 passes through the multiple island portions 13 where the second pixel circuits 321 in the first-type pixel circuit column 36 are located and the multiple bridge portions 14 arranged in the same column as the multiple island portions 13, so that a dimension of the third-type signal line 60 may be small, which is beneficial to saving the manufacturing cost of the third-type signal line 60.

In addition, the third-type signal line 60 passes through the secondary display area A2 through the multiple island portions 13 and multiple bridge portions 14, which may avoid the third-type signal line 60 covering or blocking the opening 20, and ensure that the secondary display area A2 has a high light transmittance. Thus, this ensures that the optical element 200 can collect more light and that the optical element 200 works normally.

For example, as shown in FIG. 12, the multiple columns of pixel circuits 31 further include a plurality of second-type pixel circuit columns 37. The second-type pixel circuit column 37 includes first pixel circuits 311. In the column direction, the first pixel circuits 311 in the second-type pixel circuit column 37 are located at two opposite sides of the secondary display area A2.

The second-type pixel circuit column 37 does not include second pixel circuits 321.

In the row direction, at least one second-type pixel circuit column 37 is arranged between two adjacent first-type pixel circuit columns 36.

For example, in a case where the distribution density of the plurality of first pixel units 301 is slightly different from the distribution density of the plurality of second pixel units 302, one second-type pixel circuit column 37 is arranged between two adjacent first-type pixel circuit columns 36 in the row direction. In this case, the area of the orthographic projection of the opening 20 on the plane where the substrate 10 is located is relatively small. Thus, the display effect of the secondary display area A2 may be relatively good, and the display uniformity of the display area of the display panel 100 is relatively good.

For another example, in a case where the distribution density of the plurality of first pixel units 301 is significantly different from the distribution density of the plurality of second pixel units 302, two or more second-type pixel circuit columns 37 are arranged between two adjacent first-type pixel circuit columns 36 in the row direction. In this case, the area of the orthographic projection of the opening 20 on the plane where the substrate 10 is located is relatively large. Thus, the light transmittance of the secondary display area A2 of the display panel 100 may be relatively high, and the optical element 200 may collect more light, so that the imaging effect is relatively good.

It should be understood that there are many ways to arrange a signal line electrically connected to the second-type pixel circuit column 37, which can be selected according to actual needs.

In some examples, as shown in FIG. 12, the display panel 100 further includes a fourth-type signal line 70 electrically connected to the pixel circuits 31 (i.e., the first pixel circuits 311) in the second-type pixel circuit column 37. The fourth-type signal line 70 extends substantially in the second direction. The second direction Y is the column direction of the multiple columns of pixel circuits 31. There is an included angle between the first direction X and the second direction Y, and the included angle may be 90°.

In the column direction, a portion of the fourth-type signal line 70 close to the secondary display area A2 extends to an adjacent island portion 13 or bridge portion 14 along a border of the secondary display area A2, and another portion of the fourth-type signal line 70 connected to the portion close to the secondary display area A2 passes through the secondary display area A2 through island portions 13 and bridge portions 14 arranged in the same column as the adjacent island portion 13 or bridge portion 14. The fourth-type signal line 70 passes through the island portion 13 where the second pixel circuit 321 in the first-type pixel circuit column 36 is located, but is not connected to the second pixel circuit 321.

The fourth-type signal line 70 passes through the secondary display area A2, so that a dimension of the fourth-type signal line 70 may be small. In addition, the fourth-type signal line 70 passes through the secondary display area A2 through the island portions 13 and bridge portions 14, which may avoid the fourth-type signal line 70 covering or blocking the opening 20, and ensure that the secondary display area A2 has a high light transmittance. Thus, this ensures that the optical element 200 can collect more light and that the optical element 200 works normally.

For example, a portion of the fourth-type signal line 70 located on the island portion 13 is non-overlapping with the second pixel circuit 321 located on the island portion 13.

The second pixel circuit 321 on the island portion 13 is connected to the corresponding third-type signal line 60, and the third-type signal line 60 overlaps with the second pixel circuit 321 electrically connected thereto. Therefore, the above arrangement may make a distance between the portion of the third-type signal line 60 located on the island portion 13 and the portion of the fourth-type signal line 70 located on the island portion 13 relatively large, which may ensure the accuracy of signals transmitted by the third-type signal line 60 and the fourth-type signal line 70. Accordingly, the signals received by the first-type pixel circuit column 36 and the second-type pixel circuit column 37 are relatively accurate, so that the light-emitting devices 32 electrically connected to the first-type pixel circuit column 36 and the second-type pixel circuit column 37 may perform display normally. As a result, the display panel 100 has a good display effect; it avoids interference between the signals transmitted by the third-type signal line 60 and the fourth-type signal line 70 due to a small distance between the third-type signal line 60 and the fourth-type signal line 70, and avoids misconnection between the fourth-type signal line 70 and the second pixel circuit 321 on the island portion 13.

For example, as shown in FIG. 12, the portion of the fourth-type signal line 70 located on the island portion 13 extends in the border of the island portion 13, and has a certain distance from the border line of the island portion 13. Thus, an arrangement of a plurality of fourth-type signal lines 70 may be made regular, and after the plurality of fourth-type signal lines 70 are regularly arranged, the area of the island portion 13 occupied by the fourth-type signal line 70 is small, thereby facilitating the arrangement design of other structures (such as the third-type signal lines 60 and the second pixel circuits 321) on the island portion 13. In addition, from the perspective of the manufacturing of the display panel 100 and the display apparatus 1000, the above arrangement may make the area of the island portion 13 designed to be relatively small, while the area of the opening 20 may be designed to be relatively large, which is beneficial to improving the light transmittance of the secondary display area A2 of the display panel 100, allows more light to be incident onto the optical element 200 through the opening 20, and improves the imaging quality of the optical element 200 (e.g., the camera).

In some other examples, as shown in FIG. 13, the display panel 100 further includes a fourth-type signal line 70 electrically connected to the pixel circuits 31 in the second-type pixel circuit column 37. The fourth-type signal line 70 is located in the main display area A1.

In the column direction, a portion of the fourth-type signal line 70 close to the secondary display area A2 extends in borders of the secondary display area A2. The portion of the fourth-type signal line 70 close to the secondary display area A2 extends from a first side of the secondary display area A2 along the borders of the secondary display area A2 to a second side of the secondary display area A2. The first side and second side of the secondary display area A2 are two opposite sides of the secondary display area A2 in the column direction.

For example, the fourth-type signal line 70 includes a first sub-portion 701, a second sub-portion 702 and a third sub-portion 703 connected in sequence; the first sub-portion 701 and the third sub-portion 703 are approximately located on a straight line, and the first sub-portion 701 and the third sub-portion 703 are located on opposite sides of the secondary display area A2 in the second direction Y. One end of the second sub-section 702 is connected to the first sub-section 701, the second sub-section 702 extends, along the borders of the secondary display area A2, from a side of the secondary display area A2 in the second direction Y to another side of the secondary display area A2 in the second direction Y, and the other end of the second sub-section 702 is connected to the third sub-section 703.

With the above arrangement, the fourth-type signal line 70 is only located in the main display area A1, so that the number of signal lines arranged on the island portions 13 and bridge portions 14 of the secondary display area A2 may be relatively small. During the manufacturing of the display panel 100, the areas of the island portion 13 and the bridge portion 14 may be set to be relatively small, while the area of the opening 20 may be set to be relatively large. Thus, more light enters the optical element 200 from the opening 20, which is beneficial to improving imaging quality of the optical element 200 (e.g., the camera).

For example, signals transmitted by the third-type signal line 60 and the fourth-type signal line 70 are the same. In addition, since both the third-type signal line 60 and the fourth-type signal line 70 pass through the secondary display area A2 from the main display area A1, the signals transmitted by the third-type signal line 60 and the fourth-type signal line 70 may have substantially the same transmission path from the main display area A1 to the secondary display area A2. Thus, the loss of the signal transmitted by the third-type signal line 60 is substantially the same as the loss of the signal transmitted by the fourth-type signal line 70, which is beneficial to reducing the difference in signals received by the pixel circuit 31 in the first-type pixel circuit column 36 and the pixel circuit 31 in the second-type pixel circuit column 37, and to improving the display effect of the display panel 100.

The third-type signal lines 60 include at least one of data signal lines DataL and first voltage signal lines VDDL. For example, the third-type signal lines 60 include data signal lines or first voltage signal lines. For another example, the third-type signal lines 60 include data signal lines and first voltage signal lines.

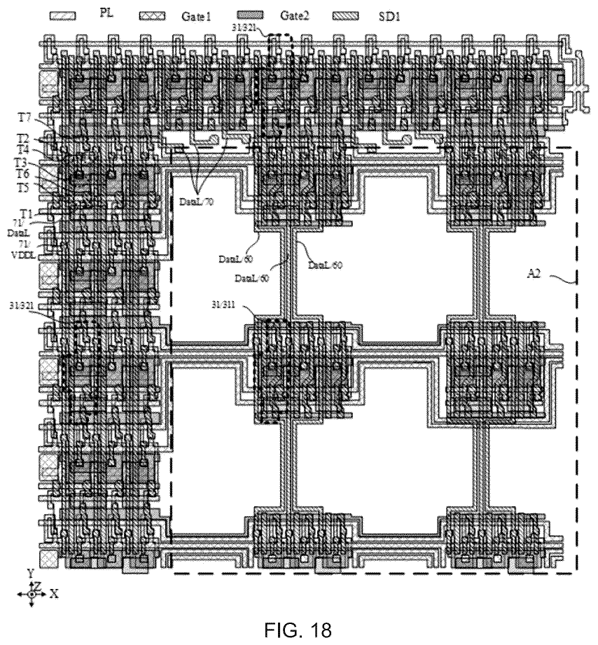

In a case where the third-type signal line 60 is a data signal line DataL (see FIG. 18), the third-type signal line 60 is electrically connected to the data signal terminal Data of the pixel circuit 31 to transmit the data signal to the data signal terminal Data.

In a case where the third-type signal line 60 is a first voltage signal line, the third-type signal line 60 is electrically connected to the first voltage signal terminal VDD of the pixel circuit 31 to transmit the first voltage signal to the first voltage signal terminal.

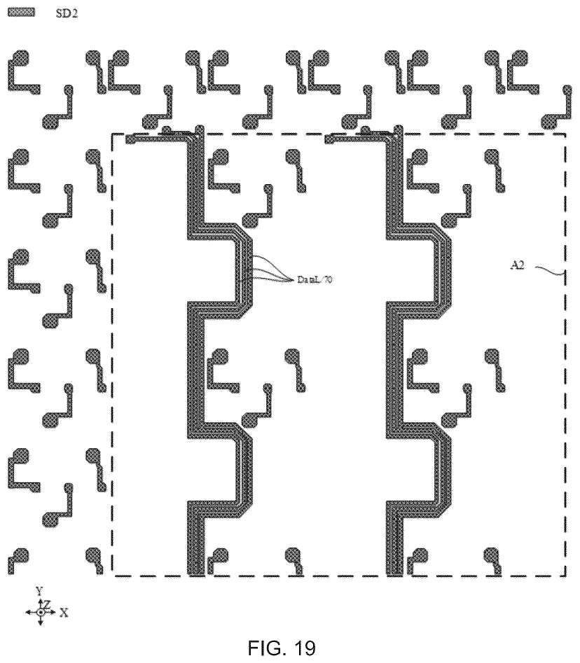

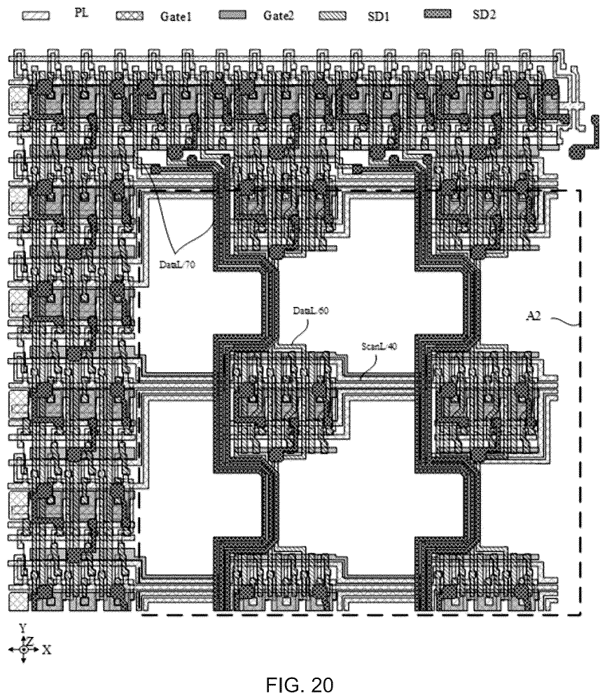

Of course, the fourth-type signal lines 70 may also include at least one of data signal lines DataL (see FIGS. 19 and 20) and first voltage signal lines VDDL.

It can be understood that, as shown in FIG. 12, the multiple columns of pixel circuits 31 further include a plurality of third-type pixel circuit columns 38, and the third-type pixel circuit column 38 includes first pixel circuits 311. The first pixel circuits 311 in the third-type pixel circuit column 38 are all located at the same side of the secondary display area A2.

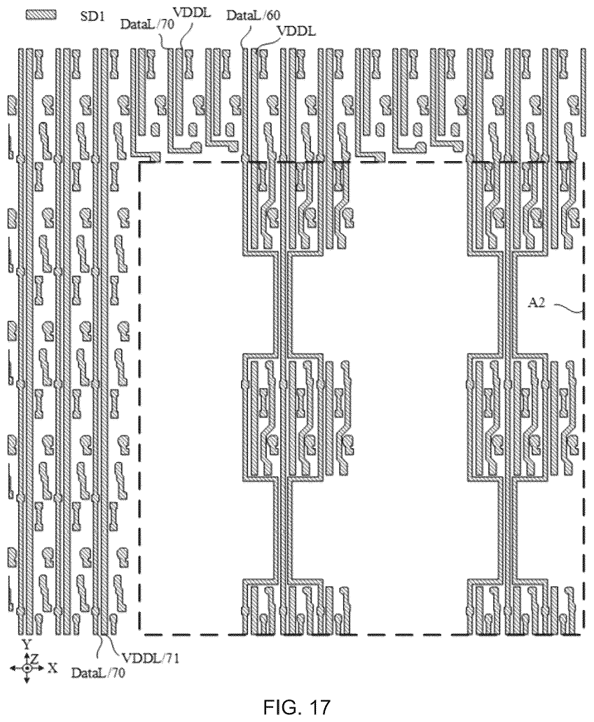

The display panel 100 further includes a seventh-type signal line 71 electrically connected to the pixel circuits 31 (i.e., the first pixel circuits 311) in the third-type pixel circuit column 38. The seventh-type signal line 71 extends in the second direction Y, and the seventh-type signal line 71 is located in the main display area A1 (see FIG. 17 for details).

The signal transmitted by the seventh-type signal line 71 is the same as the signal transmitted by the third-type signal line 60 described above.

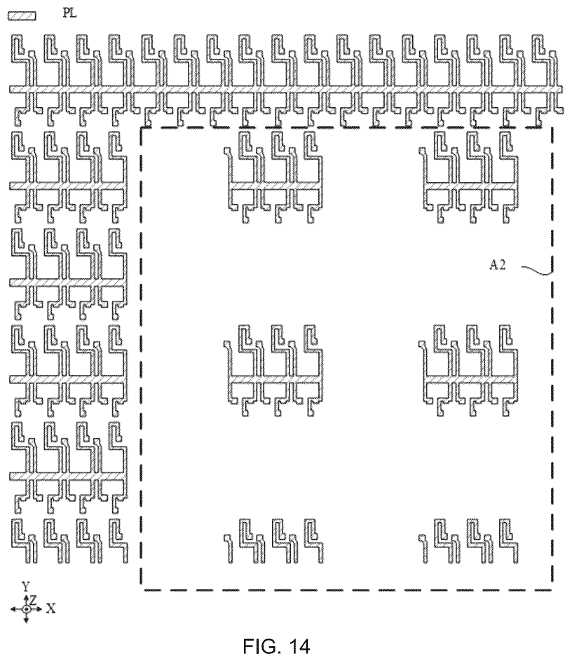

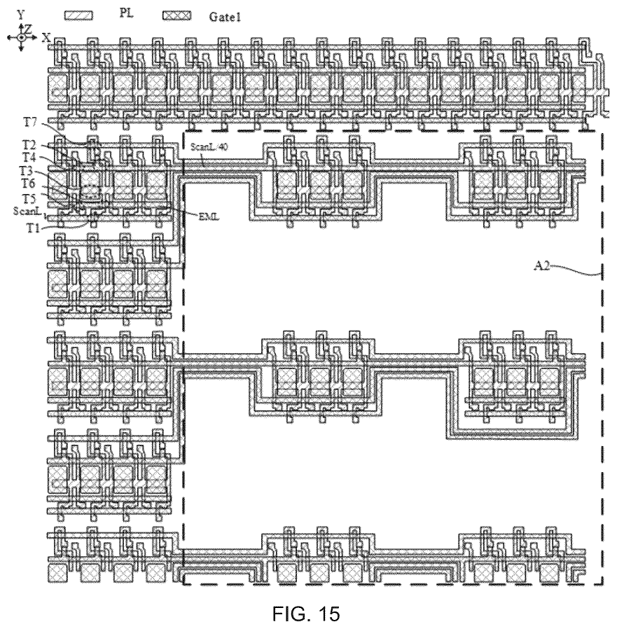

In some embodiments, as shown in FIGS. 14 to 20, the display panel 100 includes an active layer PL, a first conductive layer Gate1, a second conductive layer Gate2, a third conductive layer SD1 and a fourth conductive layer SD2 that are disposed on a side of the substrate 10 in sequence.

FIG. 14 is a top view showing a structure of the active layer PL. FIG. 15 is a top view showing a structure of the active layer PL and the first conductive layer Gate1 that are stacked. FIG. 16 is a top view showing a structure of the active layer PL, the first conductive layer Gate1 and the second conductive layer Gate2 that are stacked. FIG. 17 is a top view showing a structure of the third conductive layer SD1. FIG. 18 is a top view showing a structure of the active layer PL, the first conductive layer Gate1, the second conductive layer Gate2 and the third conductive layer SD1 that are stacked. FIG. 19 is a top view showing a structure of the fourth conductive layer SD2. FIG. 20 is a top view showing a structure of the active layer PL, the first conductive layer Gate1, the second conductive layer Gate2, the third conductive layer SD1 and the fourth conductive layer SD2 that are stacked.

It can be understood that an insulating layer (not shown in the figures) may be provided between any two adjacent film layers in the above film layers.

For example, a material of the active layer PL includes amorphous silicon, monocrystalline silicon, polycrystalline silicon, or another semiconductor material.

For example, the first conductive layer Gate1, the second conductive layer Gate2, the third conductive layer SD1 and the fourth conductive layer SD2 are each made of a conductive material. For example, the materials of the first conductive layer Gate1 and the second conductive layer Gate2 are the same, and the materials of the third conductive layer SD1 and the fourth conductive layer SD2 are the same.

For example, the conductive material is a metal material, such as aluminum (AI), silver (Ag), copper (Cu), or chromium (Cr).

It should be noted that an orthographic projection of the active layer PL on the substrate 10 overlaps with an orthographic projection of the first conductive layer Gate1 on the substrate 10. After the first conductive layer Gate1 is formed on a side of the active layer PL away from the substrate 10, the first conductive layer Gate1 can be used as a mask to perform doping treatment on the active layer PL, so that portions of the active layer PL covered by the first conductive layer Gate1 constitute active patterns of some transistors, and portions of the active layer PL not covered by the first conductive layer Gate1 constitutes conductors, which can serve as first electrodes or second electrodes of some transistors. Portions of the first conductive layer Gate1 that overlap with the active layer PL constitute gate patterns of some transistors.

Of course, the above is an introduction to the display panel 100 for the case where the transistors in the pixel circuit 31 are all LTPS transistors. In the case where the transistors in the pixel circuit 31 include LTPO transistor(s), the display panel 100 further includes a second active layer and a fifth conductive layer. The second active layer is located between the second conductive layer Gate2 and the third conductive layer SD1, and the fifth conductive layer is located between the second active layer and the third conductive layer SD1.

For example, a material of the second active layer includes a metal oxide semiconductor material, such as indium gallium zinc oxide (IGZO).

For the convenience of description, the display panel 100 is introduced below for the case where the transistors in the pixel circuit 31 are all LTPS transistors.

The first-type signal lines 40 and the second-type signal lines 50 may be located in the first conductive layer Gate1 or in the second conductive layer Gate2.

As shown in FIGS. 17 to 20, portions of the fourth-type signal lines 70 located in the main display area A1 are arranged in the third conductive layer SD1, and portions of the fourth-type signal lines 70 located in the secondary display area A2 are arranged in the third conductive layer SD1 and the fourth conductive layer SD2. The third-type signal lines 60 are located in the third conductive layer SD1.

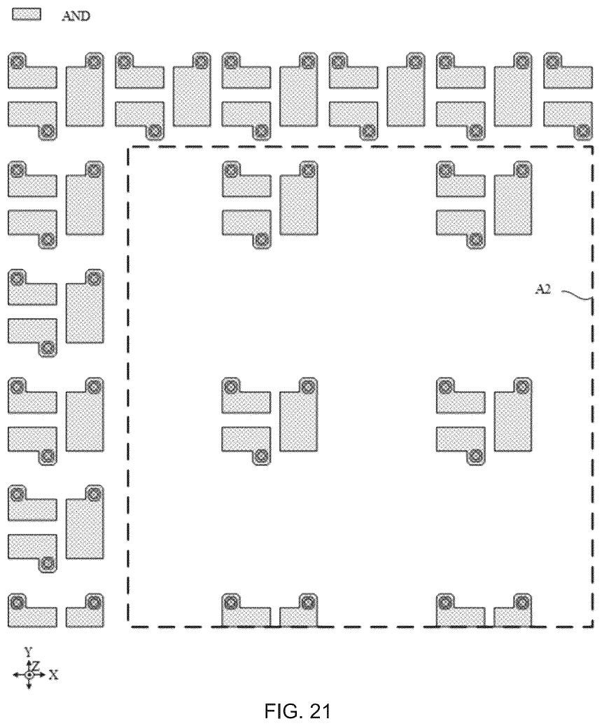

As shown in FIGS. 21 to 26, the display panel 100 further includes a second electrode layer AND and a first electrode layer NL that are stacked on the fourth conductive layer SD2 in sequence.

A light-emitting layer is disposed between the second electrode layer AND and the first electrode layer NL, and a pixel defining layer PDL is disposed between the second electrode layer AND and the light-emitting layer.

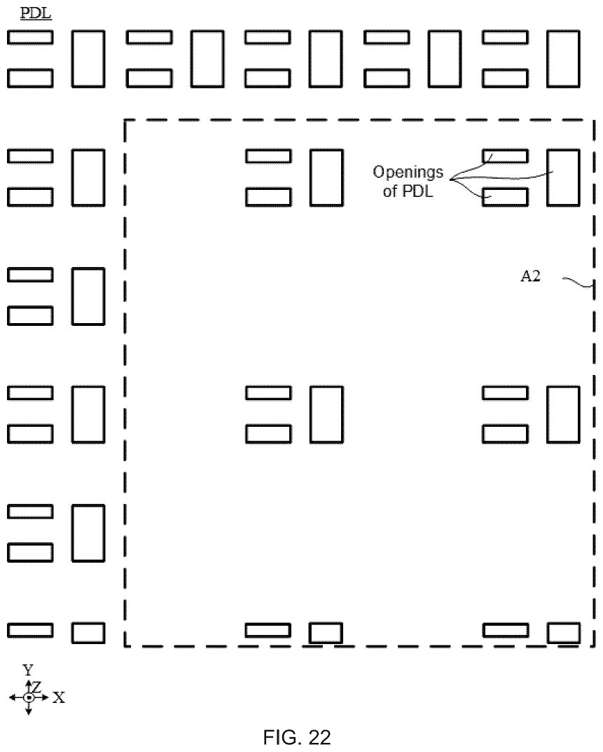

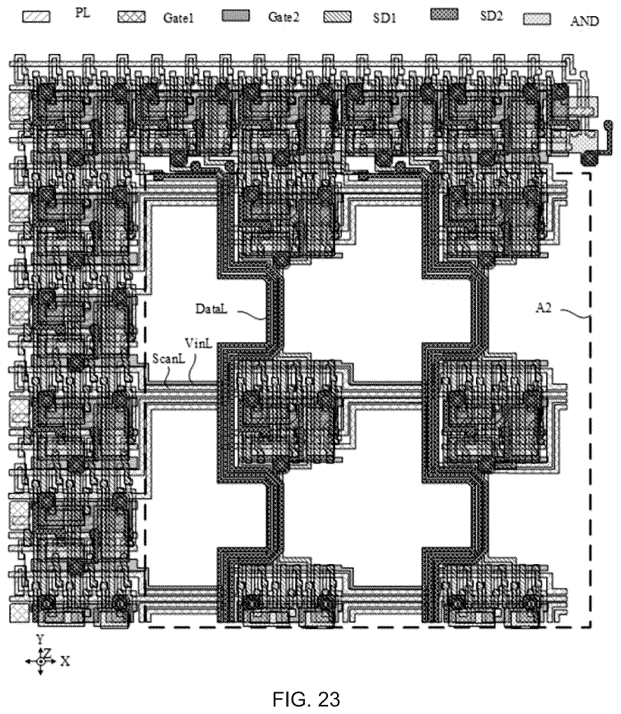

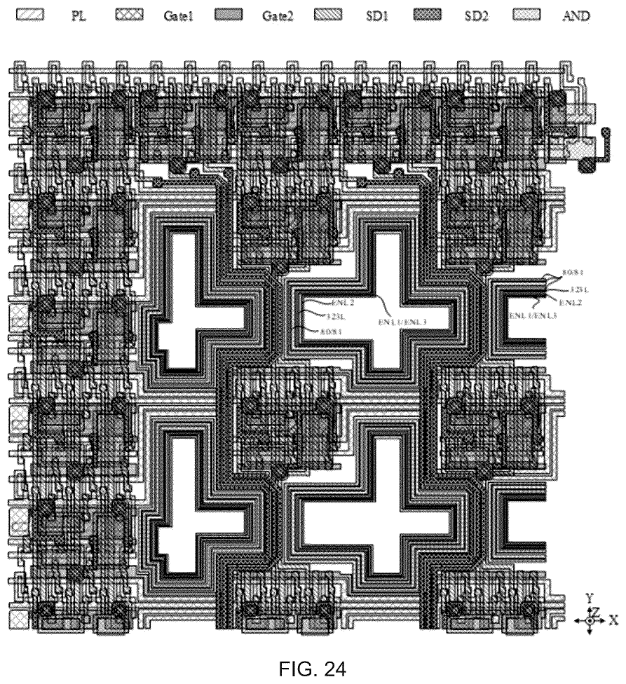

FIG. 21 is a top view showing a structure of the second electrode layer AND. FIG. 22 is a top view showing a structure of the pixel defining layer PDL, and the boxes in FIG. 22 indicate positions of openings of the pixel defining layer PDL. FIG. 23 is a top view showing a structure of the active layer PL, the first conductive layer Gate1, the second conductive layer Gate2, the third conductive layer SD1, the fourth conductive layer SD2, the second electrode layer AND and the pixel defining layer PDL that are stacked. FIG. 24 is a top view showing a structure of the active layer PL, the first conductive layer Gate1, the second conductive layer Gate2, the third conductive layer SD1, the fourth conductive layer SD2, the second electrode layer AND, the pixel defining layer PDL and an encapsulation layer ENL that are stacked.

In some embodiments, the light-emitting device 32 in the pixel unit 30 includes a first electrode, a light-emitting pattern and a second electrode. The light-emitting pattern emits light under voltages provided by the first electrode and the second electrode. The first electrode is located in the first electrode layer NL, and the second electrode is located in the second electrode layer AND.

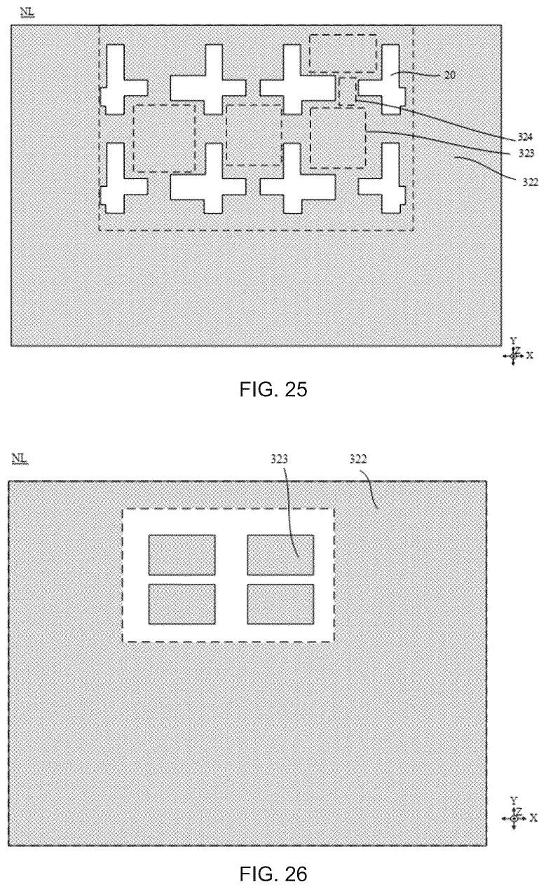

As shown in FIGS. 25 and 26, the first pixel unit 301 further includes a first electrode pattern 322 located on a side of the first pixel circuit 311 away from the first sub-substrate 11, and the first electrode pattern 322 constitutes the first electrode (e.g., a cathode) of the light-emitting device 32 in the first pixel unit 301. The first electrode pattern 322 is used to transmit a common voltage.

A plurality of first electrode patterns 322 are connected to form a one-piece structure. For example, there is no hollow portion between the plurality of first electrode patterns 322 of the one-piece structure.

The second pixel unit 302 further includes a second electrode pattern 323 located on a side of the second pixel circuit 321 away from the island portion 13, and the second electrode pattern 323 constitutes the first electrode (e.g., a cathode) of the light-emitting device 32 in the second pixel unit 302. The second electrode pattern 323 is also used to transmit the common voltage.

An arrangement of the second electrode pattern 323 in the second pixel unit 302 may be varied, and the second electrode pattern 323 may be arranged according to actual needs, which is not limited in the present disclosure.

In some examples, as shown in FIG. 25, the display panel 100 further includes a connection pattern 324 located on the bridge portion 14.

In a case where multiple second pixel units are arranged on the same island portion 13, a plurality of second electrode patterns 323 of the multiple second pixel units on the same island portion 13 are connected to each other to form a one-piece structure, and the second electrode patterns 323 on two adjacent island portions 13 are connected by the connection pattern 324.

Thus, the difference between the common voltages transmitted by the plurality of second electrode patterns 323 may be relatively small, so that the common voltage received by the light-emitting device 32 of each second pixel unit 302 is substantially the same, and each second pixel unit 302 can emit light according to a preset brightness, thereby improving the display effect of the secondary display area A2 of the display panel 100.

The second electrode pattern 323 is further connected to the first electrode pattern 322. The second electrode pattern 323 may be directly connected to the first electrode pattern 322 close to the border of the secondary display area A2, or may be connected to the first electrode pattern 322 through the connection pattern 324. Thus, a signal may be uniformly provided to the second electrode pattern 323 and the first electrode pattern 322, so that the difference between the common voltages transmitted by the second electrode pattern 323 and the first electrode pattern 322 is relatively small, and the common voltages received by the light-emitting device 32 of the second pixel unit 302 and the light-emitting device 32 of the first pixel unit 301 are substantially the same. As a result, the first pixel unit 301 and the second pixel unit 302 can both emit light according to the preset brightness, thereby improving the display consistency of the main display area A1 and the secondary display area A2 of the display panel 100, and improving the display effect of the display panel 100 and the display apparatus 1000.

For example, as shown in FIGS. 24, 25 and 27, in the case where the second electrode pattern 323 is connected to the connection pattern 324 and the first electrode pattern 322, the display panel 100 further includes a plurality of first barrier dam groups 81 located in the secondary display area A2.

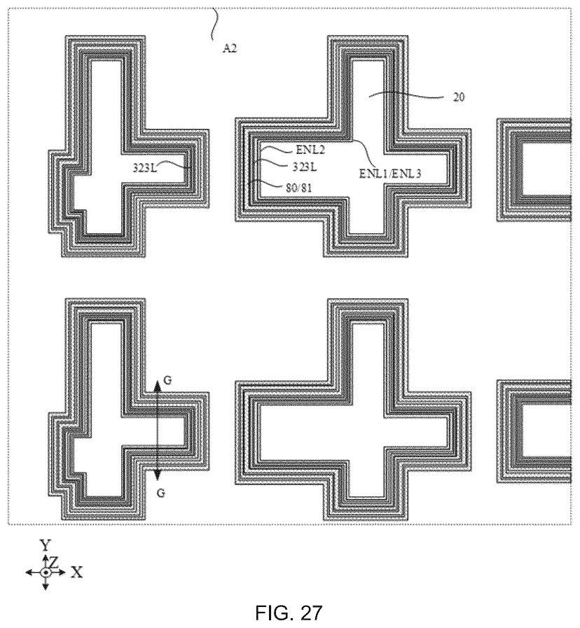

In FIGS. 24 and 27, for clarity of illustration, only border lines 323L of the second electrode patterns 323 around the opening 20 are illustrated, and the connection pattern 324 and the second electrode pattern 323 are between two adjacent border lines 323L.

A first barrier dam group 81 surrounds a single opening 20. The first barrier dam group 81 is further located between the second pixel circuit 321 and an adjacent opening 20.

A portion of the first barrier dam group 81 is located in the secondary display area A2, and the portion of the first barrier dam group 81 is located on the island portion 13 and the bridge portion 14, and has certain distances from corresponding border lines of the island portion 13 and the bridge portion 14.

The presence of the first barrier dam group 81 may prevent external water and oxygen from entering the island portion 13 or the bridge portion 14 from the sidewall of the opening 20, thereby avoiding affecting the signal transmission of the second pixel circuit 321 in the second pixel unit 302 on the island portion 13 due to erosion of water and oxygen, and avoiding affecting the light-emitting life of the light-emitting device corresponding to the second pixel circuit 321 due to erosion of water and oxygen.

In a process of manufacturing the light-emitting pattern and the second electrode pattern 323 after forming the first barrier dam group 81, it is generally necessary to manufacture a light-emitting film first, which covers the second pixel circuit and the first barrier dam group 81, and then manufacture a first electrode film on the light-emitting film. The light-emitting film and the first electrode film are both disconnected on a side of the first barrier dam group 81 away from the second pixel circuit to form the light-emitting pattern and the second electrode pattern, respectively.

Moreover, two first barrier dam groups 81 are arranged on a single bridge portion 14, and the connection pattern 324 is located on the bridge portion 14 and between the two first barrier dam groups 81.

As shown in FIGS. 24, 27 and 28, the first barrier dam group 81 includes at least one barrier dam 80.

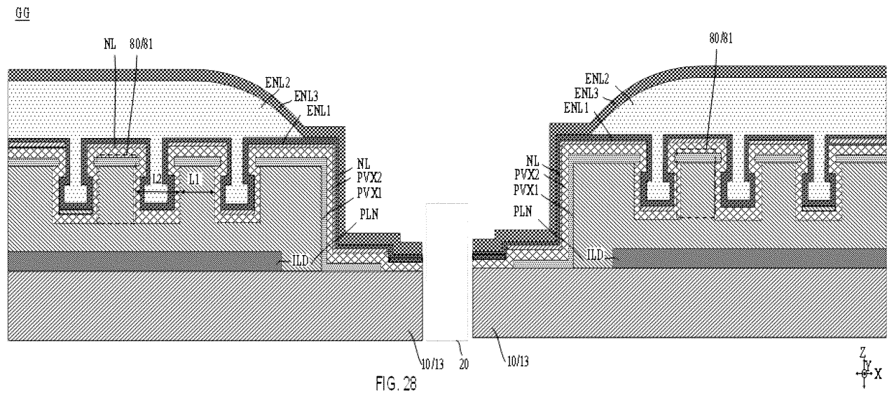

For example, as shown in FIG. 28, the first barrier dam group 81 includes one barrier dam 80, and a dimension L1 of the barrier dam 80 in a direction perpendicular to its extension direction and directing from the opening 20 adjacent to the barrier dam 80 to the island portion is 5 μm, 6 μm or 7 μm.

For example, the first barrier dam group 81 includes a plurality of barrier dams 80. The plurality of barrier dams 80 are arranged concentrically and at intervals. Here, “concentrically” means that centers of shapes of orthographic projections of the plurality of barrier dams 80 on the plane where the substrate 10 is located are the same.

As shown in FIG. 28, there is a certain distance L2 between two adjacent barrier dams 80, and the distance may be, for example, 2.5 μm, 3 μm, 3.5 μm, 4 μm or 5 μm.

For example, in a case where the first barrier dam group 81 includes two barrier dams 80, the distance L2 between the two barrier dams 80 may be 5 μm, and the dimension L1 of each barrier dam 80 in the direction perpendicular to its extension direction and directing from the opening 20 adjacent to the barrier dam 80 to the island portion may also be 5 μm.

For another example, in a case where the first barrier dam group 81 includes three barrier dams 80, the distance L2 between any two adjacent barrier dams 80 among the three barrier dams 80 may be 3 μm, and the dimension L1 of each barrier dam 80 in the direction perpendicular to its extension direction and directing from the opening 20 adjacent to the barrier dam 80 to the island portion may also be 3 μm.

It can be understood that, a flat layer PLN is provided between the third conductive layer SD1 and the fourth conductive layer SD2 of the display panel, and a first passivation layer PVX1 is provided between the fourth conductive layer SD2 and the second electrode layer AND; portions, located between the second pixel circuit and the opening (here, it refers to a region where the opening is to be formed, and the opening is manufactured after the barrier dam is formed), of the flat layer PLN and the first passivation layer PVX1 are etched to form a depression, and the bottom of the depression is located inside the flat layer PLN; and portions, located between two adjacent depressions, of the flat layer PLN and the first passivation layer PVX1 form a barrier dam 80 (referring to FIG. 28, a second passivation layer PVX2 is located on a side of the second electrode layer away from the substrate, and an interlayer dielectric layer ILD is located between the second conductive layer and the third conductive layer).

Therefore, the barrier dam 80 has a certain step difference relative to the depression. In a process of manufacturing the light-emitting device located on the island portion 13, the material of the first electrode layer will partially fall into the depression and partially be located on the barrier dam 80. As a result, the materials of the first electrode layer in the depression and on the barrier dam 80 are disconnected, so that the formed second electrode pattern 323 is disconnected at the barrier dam 80.

In some other examples, as shown in FIGS. 26, 33 and 34, in the case where multiple second pixel units are arranged on the same island portion 13, a plurality of second electrode patterns 323 of the multiple second pixel units on the same island portion 13 are connected to each other to form a one-piece structure, and second electrode patterns 323 on different island portions 13 are arranged independently of each other.

For example, the second electrode patterns 323 on two adjacent island portions are disconnected from each other.

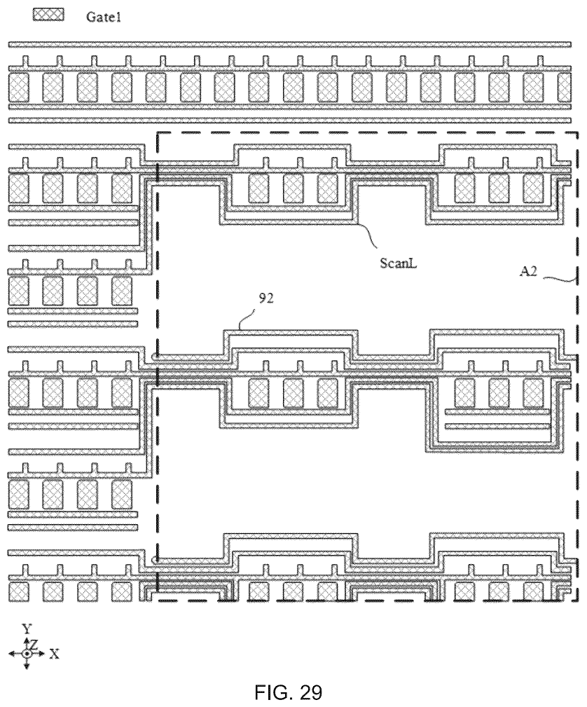

For example, in the case where the second electrode patterns 323 on different island portions 13 are arranged independently of each other, as shown in FIGS. 29 to 31, the display panel 100 further includes a fifth-type signal line 90.

The fifth-type signal line 90 includes at least one first signal sub-line 91 extending in the column direction and a plurality of second signal sub-lines 92 extending in the row direction.

The first signal sub-line 91 can be located in the main display area A1. For example, in a case where the fifth-type signal line 90 includes two first signal sub-lines 91, the two first signal sub-lines 91 may be located at two opposite sides of the secondary display area A2 in the first direction X, respectively.

The second signal sub-line 92 is located in the secondary display area A2, and extends to the main display area A1 through the island portions 13 and bridge portions 14 located in the same row to be connected to the first signal sub-line 91. The second signal sub-line 92 is further connected to the second electrode pattern 323 on each island portion 13 through which the second signal sub-line 92 passes. The fifth-type signal line 90 is used to transmit a common voltage signal to the second electrode pattern 323 on each island portion 13.

For example, the first signal sub-line 91, the second signal sub-line 92 and the second electrode pattern 323 are located in different layers.

For example, the first signal sub-line 91 is located in the third conductive layer SD1, the second signal sub-line 92 is located in the first conductive layer Gate1, and the second electrode pattern 323 is located in the first electrode layer NL.

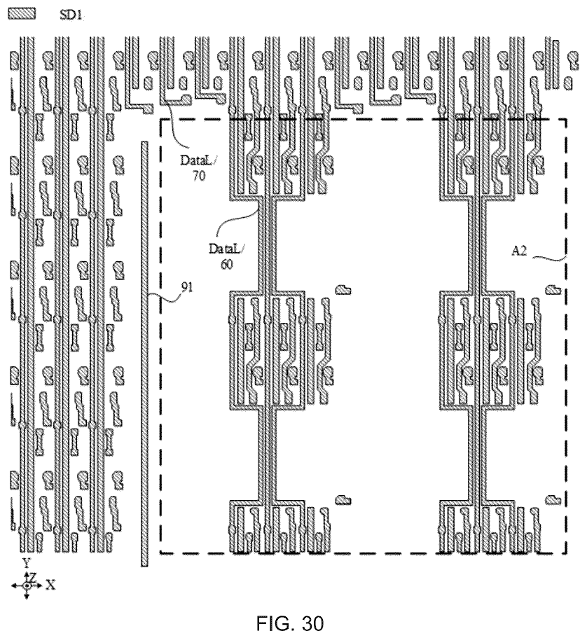

For example, as shown in FIGS. 30 to 32, the fifth-type signal line 90 further include transfer patterns 93 located in the second electrode layer AND. The second signal sub-line 92 is electrically connected to a transfer pattern 93 through a via hole penetrating through the second conductive layer Gate2, the third conductive layer SD1 and the fourth conductive layer SD2, and the transfer pattern 93 is electrically connected to the second electrode pattern 323 through a via hole. The second signal sub-line 92 is also electrically connected to the first signal sub-line 91 through a via hole penetrating through the second conductive layer Gate2.

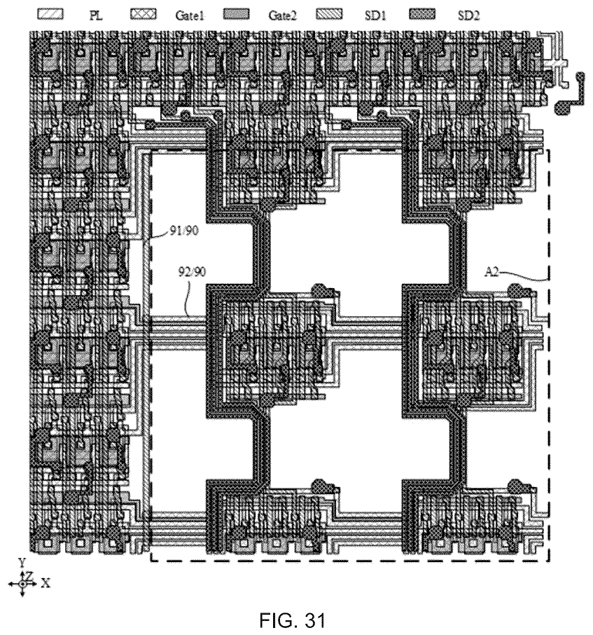

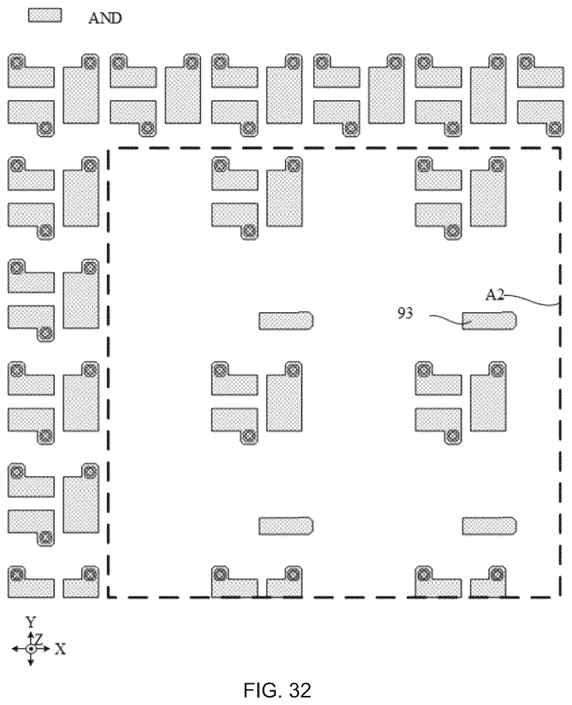

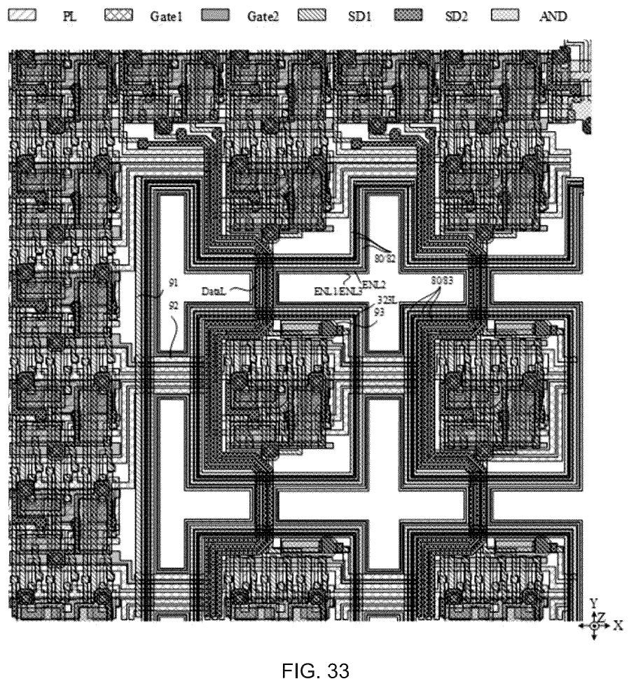

FIG. 29 is a top view showing another structure of the first conductive layer Gate1. FIG. 30 is a top view showing another structure of the third conductive layer SD1. FIG. 31 is a top view showing another structure of the active layer PL, the first conductive layer Gate1, the second conductive layer Gate2, the third conductive layer SD1 and the fourth conductive layer SD2 that are stacked. FIG. 32 is a top view showing another structure of the second electrode layer AND. FIG. 33 is a top view showing another structure of the active layer PL, the first conductive layer Gate1, the second conductive layer Gate2, the third conductive layer SD1, the fourth conductive layer SD2 and the second electrode layer AND that are stacked.

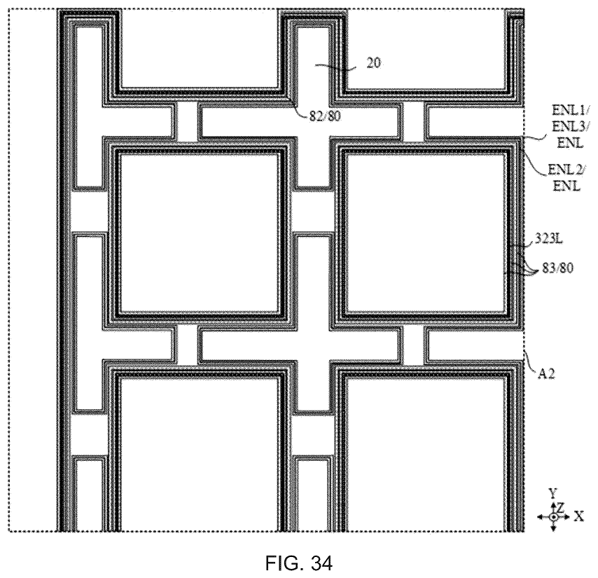

For example, as shown in FIGS. 33 and 34, the display panel 100 further includes a second barrier dam group 82 and a plurality of third barrier dam groups 83 located in the secondary display area A2.

In FIGS. 33 and 34, for clarity of illustration, only border lines 323L of the second electrode patterns 323 around the opening 20 are illustrated, and the portion in the region enclosed by the border lines 323L is the second electrode pattern 323.

The second barrier dam group 82 is arranged in the borders of the secondary display area A2 and surrounds the secondary display area A2.

A third barrier dam group 83 is located on a single island portion 13, and the third barrier dam group 83 is arranged in the borders of the corresponding island portion 13 and surrounds the second pixel units 302 on the corresponding island portion 13.

For example, the second barrier dam group 82 includes at least one barrier dam 80. In a case where the second barrier dam group 82 includes a plurality of barrier dams 80, the plurality of barrier dams 80 are arranged concentrically and at intervals.

The third barrier dam group 83 includes at least one barrier dam 80. In a case where the third barrier dam group 83 includes a plurality of barrier dams 80, the plurality of barrier dams 80 are arranged concentrically and at intervals.

The border line 323L of the second electrode pattern may be located between two adjacent barrier dams 80, or may substantially coincide with an outer border of the third barrier dam group 83.

It can be understood that, for the manufacturing processes of the at least one barrier dam 80 in the second barrier dam group 82 and the at least one barrier dam 80 in the third barrier dam group 83, reference may be made to the manufacturing process of the at least one barrier dam 80 in the first barrier dam group 81. For the dimension of each barrier dam 80 in the second barrier dam group 82 and the dimension of each barrier dam 80 in the third barrier dam group 83, reference may be made the dimension of the barrier dam 80 in the first barrier dam group 81, which will not be described in detail here.

As shown in FIGS. 24, 27, 28, 33 and 34, the display panel 100 further includes an encapsulation layer ENL disposed on a side of the first electrode layer NL away from the substrate.

In the top views of FIGS. 24, 27, 33 and 34, only borders of the encapsulation layer ENL are illustrated for clarity. It can be understood that, except for the openings 20, all other regions are covered by the encapsulation layer ENL.

For example, the encapsulation layer ENL can be a thin film encapsulation layer, which can encapsulate the above-mentioned pixel units, so that the pixel circuits 31 and the light-emitting devices 32 are isolated from external water vapor, thereby improving the light-emitting performance and light-emitting life of the light-emitting devices 32, and avoiding the oxidation of the pixel circuits 31 and the light-emitting devices 32 by water vapor under the invasion of water vapor.

Compared with the barrier dam 80 and the border line 323L of the second electrode pattern located on the same side of the opening 20, the distance between the border line of the encapsulation layer ENL and the opening 20 is the shortest.

The encapsulation layer ENL includes inorganic encapsulation layer(s) and an organic encapsulation layer. The inorganic encapsulation layer(s) may include a first inorganic encapsulation layer ENL1 and a second inorganic encapsulation layer ENL3. The organic encapsulation layer ENL2 may be located between the first inorganic encapsulation layer ENL1 and the second inorganic encapsulation layer ENL3.

For example, the inorganic encapsulation layer may be made of an inorganic material, and may be manufactured by a vapor deposition process. The organic encapsulation layer may be made of an organic material, and may be formed by an inkjet printing process. The material of the inorganic encapsulation layer may be OC (optical clear) glue, which is beneficial to encapsulating the pixel units on the island portion 13.

It can be understood that, the organic encapsulation layer ENL2 is mainly used for planarization and stress relief, and the first inorganic encapsulation layer ENL1 and the second inorganic encapsulation layer ENL3 in the inorganic encapsulation layers are mainly used to block water and oxygen, and wrap the organic encapsulation layer ENL2 located between the first inorganic encapsulation layer ENL1 and the second inorganic encapsulation layer ENL3. The first barrier dam group 81 is taken as an example, the first barrier dam group 81 has a certain height, and therefore, the first barrier dam group 81 can be used to block the material of the organic encapsulation layer ENL2, the organic encapsulation layer ENL2 is within a region enclosed by the first barrier dam group 81, and there is no organic encapsulation layer ENL2 outside the region enclosed by the first barrier dam group 81. The inorganic encapsulation layer covers the first barrier dam group 81.

The formation of the opening 20 in the display panel 100 is briefly introduced below. In the case where the display panel 100 includes the connection pattern 324, after the first barrier dam group 81 is formed, the second electrode layer AND, the light-emitting layer, the first electrode layer NL and the encapsulation layer ENL are sequentially formed on the side of the first barrier dam group 81 and the pixel circuit 31 away from the substrate 10, and then portions, in a region where the opening is to be formed, of the encapsulation layer ENL, the first electrode layer NL and the substrate 10 are etched to form the opening 20 that passes through the display panel 100.

The above are only specific embodiments of the present disclosure, but the scope of protection of the present disclosure is not limited thereto, and any person skilled in the art may conceive of variations or replacements within the technical scope of the present disclosure, which shall fall within the protection scope of the present disclosure. Therefore, the protection scope of the present disclosure should be determined by the protection scope of the claims.

What is claimed is:

1. A display panel having a main display area and a secondary display area located on at least one side of the main display area, the display panel comprising:
a substrate;
a plurality of pixel units located on a side of the substrate, wherein the plurality of pixel units include a plurality of first pixel units and a plurality of second pixel units; the plurality of first pixel units are located in the main display area, and the plurality of second pixel units are located in the secondary display area; and a light transmittance of the main display area is less than a light transmittance of the secondary display area; and
a plurality of openings that at least penetrate through the substrate, wherein the plurality of openings are located in the secondary display area, multiple second pixel units are arranged around at least one of the plurality of openings, and orthographic projections of the plurality of openings on the substrate are non-overlapping with orthographic projections of the plurality of second pixel units on the substrate.

2. The display panel according to claim 1, wherein the substrate includes a first sub-substrate located in the main display area and a second sub-substrate located in the secondary display area, the first sub-substrate and the second sub-substrate are connected, and the plurality of first pixel units are located on the first sub-substrate; and
the second sub-substrate includes:
a plurality of island portions arranged in multiple rows and multiple columns, wherein each island portion is provided thereon with at least one second pixel unit in the plurality of second pixel units; and
a plurality of bridge portions located between island portions in a same row and between island portions in a same column; two adjacent island portions are connected by a bridge portion in the plurality of bridge portions; and island portions and bridge portions are arranged around the at least one opening.

3. The display panel according to claim 2, wherein a pixel unit in the plurality of pixel units includes a pixel circuit; a first pixel unit in the plurality of first pixel units includes a first pixel circuit, and a second pixel unit in the plurality of second pixel units includes a second pixel circuit;
pixel circuits of the plurality of pixel units are arranged in multiple rows, and the multiple rows of pixel circuits includes a plurality of first-type pixel circuit rows; a first-type pixel circuit row in the plurality of first-type pixel circuit rows includes first pixel circuits and second pixel circuits; and in a row direction, the first pixel circuits in the first-type pixel circuit row are located at two opposite sides of the secondary display area;
the display panel further comprises a first-type signal line electrically connected to pixel circuits in the first-type pixel circuit row; and
in the row direction, the first-type signal line passes through the secondary display area from the main display area through multiple island portions where the second pixel circuits in the first-type pixel circuit row are located and multiple bridge portions arranged in the same row as the multiple island portions.

4. The display panel according to claim 3, wherein the multiple rows of pixel circuits further include a plurality of second-type pixel circuit rows; a second-type pixel circuit row in the plurality of second-type pixel circuit rows includes first pixel circuits; in the row direction, the first pixel circuits in the second-type pixel circuit row are located at two opposite sides of the secondary display area; and in a column direction, at least one second-type pixel circuit row is arranged between two adjacent first-type pixel circuit rows;
the display panel further comprises a second-type signal line electrically connected to pixel circuits in the second-type pixel circuit row; and
in the row direction, a portion of the second-type signal line close to the secondary display area extends to an adjacent island portion or bridge portion along a border of the secondary display area, and another portion of the second-type signal line connected to the portion close to the secondary display area passes through the secondary display area through island portions and bridge portions arranged in a same row as the adjacent island portion or bridge portion.

5. The display panel according to claim 4, wherein a portion of the second-type signal line located on the island portion extends in a border of the island portion; and/or
a portion of the second-type signal line located on the island portion is non-overlapping with a second pixel circuit located on the island portion.

6.-7. (canceled)

8. The display panel according to claim 3, wherein the first-type signal line includes at least one of scan signal lines, enable signal lines, and initial signal lines.

9. The display panel according to claim 2, wherein there are multiple second pixel units on the island portion; for the island portions located in the same row, second pixel circuits of second pixel units on each island portion are arranged in a same row.

10. The display panel according to claim 2, wherein a pixel unit in the plurality of pixel units includes a pixel circuit; a first pixel unit in the plurality of first pixel units includes a first pixel circuit, and a second pixel unit in the plurality of second pixel units includes a second pixel circuit;
pixel circuits of the plurality of pixel units are arranged in multiple columns, and the multiple columns of pixel circuits includes a plurality of first-type pixel circuit columns; a first-type pixel circuit column in the plurality of first-type pixel circuit columns includes first pixel circuits and second pixel circuits; and in a column direction, the first pixel circuits in the first-type pixel circuit column are located at two opposite sides of the secondary display area;
the display panel further comprises a third-type signal line electrically connected to pixel circuits in the first-type pixel circuit column; and
in the column direction, the third-type signal line passes through the secondary display area from the main display area through multiple island portions where the second pixel circuits in the first-type pixel circuit column are located and multiple bridge portions arranged in the same column as the multiple island portions.

11. The display panel according to claim 10, wherein the multiple columns of pixel circuits further include a plurality of second-type pixel circuit columns; a second-type pixel circuit column in the plurality of second-type pixel circuit columns includes first pixel circuits; in the column direction, the first pixel circuits in the second-type pixel circuit column are located at two opposite sides of the secondary display area; and in the row direction, at least one second-type pixel circuit column is arranged between two adjacent first-type pixel circuit columns;
the display panel further comprises a fourth-type signal line electrically connected to pixel circuits in the second-type pixel circuit column; and
in the column direction, a portion of the fourth-type signal line close to the secondary display area extends to an adjacent island portion or bridge portion along a border of the secondary display area, and another portion of the fourth-type signal line connected to the portion close to the secondary display area passes through the secondary display area through island portions and bridge portions arranged in a same column as the adjacent island portion or bridge portion.

12. The display panel according to claim 11, wherein a portion of the fourth-type signal line located on the island portion extends in a border of the island portion; and/or
a portion of the fourth-type signal line located on the island portion is non-overlapping with a second pixel circuit located on the island portion.

13. (canceled)

14. The display panel according to claim 10, wherein the multiple columns of pixel circuits further include a plurality of second-type pixel circuit columns; a second-type pixel circuit column in the plurality of second-type pixel circuit columns includes first pixel circuits; in the column direction, the first pixel circuits in the second-type pixel circuit column are located at two opposite sides of the secondary display area; and in the row direction, at least one second-type pixel circuit column is arranged between two adjacent first-type pixel circuit columns;
the display panel further comprises a fourth-type signal line electrically connected to pixel circuits in the second-type pixel circuit column, and the fourth-type signal line is located in the main display area; and
in the column direction, a portion of the fourth-type signal line close to the secondary display area extends from a first side of the secondary display area along borders of the secondary display area to a second side of the secondary display area; and the first side and second side of the secondary display area are two opposite sides of the secondary display area in the column direction.

15. The display panel according to claim 10, wherein there are multiple second pixel units on the island portion; for the island portions located in the same column, second pixel circuits of second pixel units on each island portion are arranged in a same column.

16. (canceled)

17. The display panel according to claim 10, wherein the third-type signal line includes at least one of data signal lines and first voltage signal lines.

18. The display panel according to claim 2, wherein a pixel unit in the plurality of pixel units includes a pixel circuit;
a first pixel unit in the plurality of first pixel units includes a first pixel circuit and a first electrode pattern located on a side of the first pixel circuit away from the first sub-substrate; a plurality of first electrode patterns are connected to form a one-piece structure; and a second pixel unit in the plurality of second pixel units includes a second pixel circuit and a second electrode pattern located on a side of the second pixel circuit away from the island portion, wherein
second electrode patterns on different island portions are arranged independently of each other; or the display panel comprises a connection pattern located on the bridge portion, second electrode patterns on two adjacent island portions are connected by the connection pattern, and the second electrode patterns are further connected to the first electrode pattern.

19. The display panel according to claim 18, wherein in a case where the second electrode patterns are connected to the connection pattern and the first electrode pattern, the display panel further comprises a plurality of first barrier dam groups located in the secondary display area; and
a first barrier dam group in the plurality of first barrier dam groups surrounds a single opening in the plurality of openings, and the first barrier dam group is further located between the second pixel circuit and an adjacent opening.

20. The display panel according to claim 19, wherein the first barrier dam group includes at least one barrier dam; and in a case where the first barrier dam group includes a plurality of barrier dams, the plurality of barrier dams are arranged concentrically and at intervals.

21. The display panel according to claim 18, wherein in a case where the second electrode patterns on different island portions are arranged independently of each other,
the display panel further comprises a fifth-type signal line for transmitting a common voltage signal;
the fifth-type signal line includes at least one first signal sub-line extending in a column direction and a plurality of second signal sub-lines extending in a row direction;
a first signal sub-line in the at least one first signal sub-line is located in the main display area; a second signal sub-line in the plurality of second signal sub-lines is located in the secondary display area and extends to the main display area through island portions and bridge portions located in the same row to be connected to the first signal sub-line; and the second signal sub-line is further connected to the second electrode pattern on each island portion through which the second signal sub-line passes.

22. (canceled)

23. The display panel according to claim 21, wherein the display panel further comprises a second barrier dam group and a plurality of third barrier dam groups located in the secondary display area; and
the second barrier dam group is arranged in borders of the secondary display area and surrounds the secondary display area; and
a third barrier dam group in the plurality of third barrier dam groups is located on a single island portion in the plurality of island portions, and the third barrier dam group is arranged in borders of the corresponding island portion and surrounds the at least one second pixel unit on the corresponding island portion.

24. The display panel according to claim 23, wherein the second barrier dam group includes at least one barrier dam; in a case where the second barrier dam group includes a plurality of barrier dams, the plurality of barrier dams are arranged concentrically and at intervals; and
the third barrier dam group includes at least one barrier dam; in a case where the third barrier dam group includes a plurality of barrier dams, the plurality of barrier dams are arranged concentrically and at intervals.

25. A display apparatus, comprising the display panel according to claim 1 and an optical element, wherein
the optical element is located on a non-light-exit side of the display panel, and is located on the secondary display area of the display panel.
